(19) United States
(12) Patent Application Publication
(10) Pub. No.: US 2024/0349580 A1
(43) Pub. Date: Oct. 17, 2024

(54) TOUCH SENSING UNIT AND DISPLAY DEVICE INCLUDING THE SAME

(71) Applicant: Samsung Display Co., Ltd., Gyeonggi-do (KR)

(72) Inventors: Hyun Eok SHIN, Yongin-si (KR); Ju Hyun LEE, Yongin-si (KR); Dong Min LEE, Yongin-si (KR)

(21) Appl. No.: 18/530,624

(22) Filed: Dec. 6, 2023

(30) Foreign Application Priority Data
Apr. 17, 2023 (KR) 10-2023-0049902

(51) Int. Cl. H10K 59/80; G06F 3/041; G06F 3/044; H10K 59/40

(52) U.S. Cl. CPC H10K 59/8792; G06F 3/0412; G06F 3/0445; H10K 59/40

(57) ABSTRACT

A touch sensing unit having a substrate including an emission area and a non-emission area, a light emitting element positioned on the substrate and overlapping the emission area, a thin film encapsulation layer on the light emitting element and a touch sensor layer positioned on the thin film encapsulation layer, including a touch insulating layer on the thin film encapsulation layer, a touch metal layer on the touch insulating layer, and a touch protection layer on the touch metal layer, including a first conductive layer on the touch insulating layer, a second conductive layer on the first conductive layer and a first inclined surface connecting the first surface to the second surface and a third conductive layer covering the first inclined surface and the second surface of the second conductive layer.

This application claims priority to Korean Patent Application No. 10-2023-0049902, filed on Apr. 17, 2023, and all the benefits accruing therefrom under 35 U.S.C. § 119, the content of which in its entirety is herein incorporated by reference.

### BACKGROUND

### 1. Technical Field

The present disclosure relates to a touch sensing unit and a display device including the same.

### 2. Description of the Related Art

With the advance of an information-oriented society, more and more demands are placed on display devices for displaying images in various ways. For example, display devices are employed in various electronic devices such as smartphones, digital cameras, laptop computers, navigation devices, and smart televisions.

In recent years, a touch member that recognizes a touch input has been applied to a display device mainly in a smartphone or a tablet PC. The touch member is formed directly on a display panel to simplify the process and provide for a thin display device.

The display device includes a display panel for generating and displaying an image and various input devices.

### SUMMARY

Embodiments of the invention provide a touch sensing unit capable of improving a defect of a reddish color being seen from the outside of a display device.

Embodiments of the invention also provide a touch sensing unit having an improved side reflectivity of the display device.

However, embodiments of the invention are not restricted to those set forth herein. The above and other embodiments of the invention will become more apparent to one of ordinary skill in the art to which the invention pertains by referencing the detailed description of given below.

An embodiment of a touch sensing unit includes a substrate including an emission area and a non-emission area, a light emitting element positioned on the substrate and overlapping the emission area, a thin film encapsulation layer on the light emitting element and overlapping the emission area and the non-emission area and a touch sensor layer on the thin film encapsulation layer. The touch sensor layer includes a touch insulating layer on the thin film encapsulation layer and overlapping the emission area and the non-emission area, a touch metal layer on the touch insulating layer and overlapping the non-emission area, a low reflection layer on the touch metal layer, a passivation layer on the low reflection layer and a touch protection layer on the touch insulating layer and the passivation layer and overlapping the emission area and the non-emission area. The touch metal layer includes a first conductive layer on the touch insulating layer and a second conductive layer on the first conductive layer, wherein the second conductive layer includes a first surface in contact with the first conductive layer, a second surface opposite to the first surface, and a first inclined surface connecting the first surface to the second surface. The passivation layer is positioned on the first inclined surface of the second conductive layer, the low reflection layer is positioned between the first inclined surface of the second conductive layer and the passivation layer, and further includes a third surface positioned to face the touch protection layer, and the second surface of the second conductive layer and the third surface of the low reflection layer are aligned in a first direction and are positioned on the same plane.

In an embodiment, the passivation layer may further include a fourth surface positioned to face the touch protection layer, and the second surface of the second conductive layer, the third surface of the low reflection layer, and the fourth surface of the passivation layer are aligned in the first direction and positioned on the same plane.

In an embodiment, the low reflection layer and the passivation layer may be disposed on the touch insulating layer to be in partial contact therewith, and the second conductive layer is not in contact with the touch insulating layer.

In an embodiment, the first conductive layer may further include a second inclined surface extending from the first inclined surface of the second conductive layer, and the second inclined surface may be in contact with the low reflection layer.

In an embodiment, a touch sensing unit includes a first inclination angle formed by one surface of the first conductive layer in contact with the second conductive layer and the first inclined surface of the second conductive layer ranges from about 600 to about 90°.

In an embodiment, a thickness of the low reflection layer in the first direction may be smaller than a thickness of the passivation layer, a thickness of the low reflection layer in the first direction ranges from about 100 Å to about 200 Å, the low reflection layer contains amorphous silicon (a-Si) and silicon carbonite (SiC), and the passivation layer comprises an inorganic layer such as SiNx and SiO2.

In an embodiment, the first conductive layer and the second conductive layer may be formed in a mesh shape, and the passivation layer and the low reflection layer are formed in a mesh shape to surround side surfaces of the first conductive layer and the second conductive layer.

In an embodiment, a touch sensing unit may further include an opening formed by the passivation layer and the low reflection layer, wherein the opening overlaps the emission area.

In an embodiment, the touch metal layer may further include a third conductive layer disposed on the second conductive layer, wherein one surface of the third conductive layer is facing the second conductive layer and is disposed in partial contact with the third surface of the low reflection layer, and wherein a first side surface of the third conductive layer and a second side surface of the low reflection layer may be aligned on the same plane in a direction that is perpendicular to the first direction.

In an embodiment, the passivation layer may further include a fourth surface positioned to face the touch protection layer, and one surface of the third conductive layer facing the second conductive layer may be not in contact with the fourth surface of the passivation layer.

In an embodiment, a width of the third conductive layer in the first direction may be greater than a width of the first conductive layer in the first direction.

In an embodiment, the first conductive layer and the third conductive layer may contain titanium (Ti), and the second conductive layer contains copper (Cu).

In an embodiment, a touch sensing unit may further include a connection electrode overlapping the non-emission area and positioned between the thin film encapsulation layer and the touch insulating layer and a touch contact hole passing through a center of the touch insulating layer, wherein the connection electrode and the touch metal layer may be electrically connected by the touch contact hole.

In an embodiment, the touch metal layer may include a driving electrode and a sensing electrode.

An embodiment of a touch sensing unit includes a substrate including an emission area and a non-emission area, a light emitting element positioned on the substrate and overlapping the emission area, a thin film encapsulation layer on the light emitting element and overlapping the emission area and the non-emission area and a touch sensor layer positioned on the thin film encapsulation layer. The touch sensor layer includes a touch insulating layer on the thin film encapsulation layer and overlapping the emission area and the non-emission area, a touch metal layer on the touch insulating layer and overlapping the non-emission area and a touch protection layer on the touch metal layer. The touch metal layer includes a first conductive layer on the touch insulating layer, a second conductive layer on the first conductive layer, the second conductive layer including a first surface in contact with the first conductive layer, a second surface opposite to the first surface, and a first inclined surface connecting the first surface to the second surface, and a third conductive layer covering the first inclined surface and the second surface of the second conductive layer, wherein the first side surface located at both ends of the first conductive layer in the first direction and the second side surface located at both ends of the third conductive layer in the first direction are aligned on the same plane.

In an embodiment, a width of the first conductive layer in the first direction may be greater than a width of the second conductive layer, and greater than or equal to a width of the third conductive layer.

In an embodiment, a touch sensing unit may further include an angle formed by one surface of the first conductive layer in contact with the second conductive layer, wherein the first inclined surface of the second conductive layer ranges from about 600 to about 90°.

In an embodiment, the first conductive layer and the third conductive layer may contain titanium nitride (TiN), and the second conductive layer contains copper (Cu).

An embodiment of a touch sensing unit includes a substrate including a display area having an emission area and a non-emission area and a non-display area, a thin film encapsulation layer on the substrate and overlapping the display area and the non-display area, a touch insulating layer on the thin film encapsulation layer and overlapping the display area and the non-display area, a touch electrode on the touch insulating layer and overlapping the non-emission area, a touch signal line on the touch insulating layer and overlapping the non-display area, a low reflection layer overlapping the non-display area and positioned on the touch signal line, a passivation layer overlapping the non-display area and positioned on the low reflection layer and a touch protection layer overlapping the display area and the non-display area and positioned on the passivation layer. The touch signal line includes a first conductive layer on the touch insulating layer and a second conductive layer on the first conductive layer, wherein the second conductive layer includes a first surface in contact with the first conductive layer, a second surface opposite to the first surface, and a first inclined surface connecting the first surface to the second surface. The passivation layer is positioned on the first inclined surface of the second conductive layer, the low reflection layer is positioned between the first inclined surface of the second conductive layer and the passivation layer, wherein the low reflection layer further includes a third surface disposed to face the touch protection layer, and the second surface of the second conductive layer and the third surface of the low reflection layer are aligned on the same plane.

In an embodiment, the touch signal line may further include a third conductive layer disposed on the second conductive layer, wherein one surface of the third conductive layer is disposed in partial contact with the third surface of the low reflection layer, and a side surface of the third conductive layer and a side surface of the low reflection layer are aligned in a direction perpendicular to the first direction.

The touch sensing unit according to an embodiment may improve side reflectivity as recognized from the outside of the display device.

However, effects according to embodiments are not limited to those exemplified above and various other effects are incorporated herein.

### BRIEF DESCRIPTION OF THE DRAWINGS

These and/or other features of embodiments of the invention will become apparent and more readily appreciated from the following description of the embodiments, taken in conjunction with the accompanying drawings, in which:

FIG. 1 is a perspective view of an electronic device, according to an embodiment;

FIG. 2 is a perspective view illustrating a display device included in an electronic device, according to an embodiment;

FIG. 3 is a cross-sectional view illustrating an example of a display panel taken along line X1-X1′ of FIG. 2, according to an embodiment;

FIG. 4 is a plan view illustrating a touch sensor layer of a display device, according to an embodiment;

FIG. 5 is a plan view of a touch sensor layer, presenting an enlargement of area A of FIG. 4, according to an embodiment;

FIG. 6 is a cross-sectional view showing a schematic cross section taken along line X2-X2′ of FIG. 5, according to an embodiment;

FIG. 7 is an enlarged plan view of area C of FIG. 5, according to an embodiment;

FIG. 8 is a cross-sectional view showing a schematic cross section taken along line X3-X3′ of FIG. 7, according to an embodiment;

FIG. 9 is an enlarged cross-sectional view of area C1 of FIG. 8, according to an embodiment;

FIG. 10 is an enlarged plan view of area E of FIG. 5, according to an embodiment;

FIG. 11 is a cross-sectional view showing a schematic cross section taken along line X5-X5′ of FIG. 10, according to an embodiment;

FIG. 12 is an enlarged plan view of area T of FIG. 4, according to an embodiment;

FIG. 13 is a cross-sectional view illustrating a schematic cross section taken along line X9-X9′ of FIG. 12, according to an embodiment;

FIG. 14 is an enlarged plan view of area C of FIG. 5, according to another embodiment;

FIG. 15 is a cross-sectional view showing a schematic cross section taken along line X6-X6′ of FIG. 14, according to another embodiment;

FIG. 16 is an enlarged cross-sectional view of area C3 of FIG. 15, according to another embodiment;

FIG. 17 is an enlarged cross-sectional view of area C4 of FIG. 16, according to an embodiment;

FIG. 18 is a cross-sectional view showing a schematic cross section taken along line X9-X9′ of FIG. 12, according to another embodiment;

FIG. 19 is a graph showing side reflectivity for each wavelength according to the thickness W341 of the low reflection layer 341, according to an embodiment;

FIG. 20 is an enlarged plan view of area C of FIG. 5, according to another embodiment;

FIG. 21 is a cross-sectional view illustrating a schematic cross-section taken along line X7-X7′ of FIG. 20, according to another embodiment;

FIG. 22 is an enlarged cross-sectional view of area C5 of FIG. 21, according to an embodiment;

FIG. 23 is an enlarged cross-sectional view of area C7 of FIG. 22, according to an embodiment; and

FIG. 24 is a cross-sectional view showing a schematic cross section taken along line X9-X9′ of FIG. 13, according to still another embodiment.

### DETAILED DESCRIPTION OF THE EMBODIMENTS

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions may be exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described with reference to the accompanying drawings.

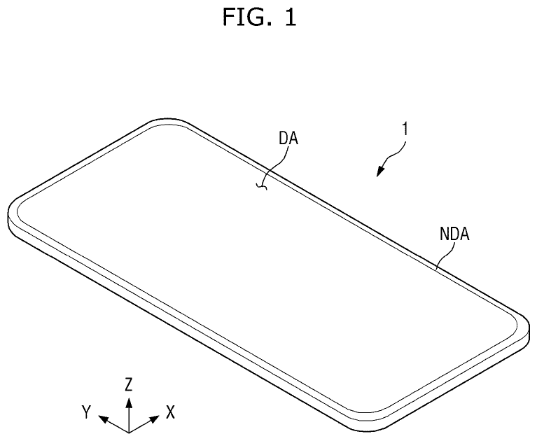

FIG. 1 is a perspective view of an electronic device, according to an embodiment.

In an embodiment and referring to FIG. 1, an electronic device 1 displays a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

In an embodiment, FIG. 1 defines a first direction X, a second direction Y, and a third direction Z. The first direction X and the second direction Y may be directed in a direction that is perpendicular to each other, the first direction X and the third direction Z may be perpendicular to each other, and the second direction Y and the third direction Z may be perpendicular to each other. It may be understood that the first direction X refers to a horizontal direction in the drawing, the second direction Y refers to a vertical direction in the drawing, and the third direction Z refers to an upward and downward direction (i.e., a thickness direction) in the drawing. In the following specification, unless otherwise stated, “direction” may refer to both of directions extending along the direction. Further, when it is necessary to distinguish both “directions” extending in both sides, one side will be referred to as “one side in the direction” and the other side will be referred to as “the other side in the direction.” Referring to FIG. 1, a direction in which an arrow indicating a direction is directed is referred to as one side, and an opposite direction thereto is referred to as the other side.

Hereinafter, in an embodiment and for simplicity of description, when referring to an electronic device 1 or the surfaces of each member constituting the electronic device 1, one surface facing one side in the direction in which the image is displayed, that is, the third direction Z is referred to as a top surface, and the opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing the relative position of each of the members of the electronic device 1, one side of the third direction Z may be referred to as an upper side and the other side of the third direction Z may be referred to as a lower side.

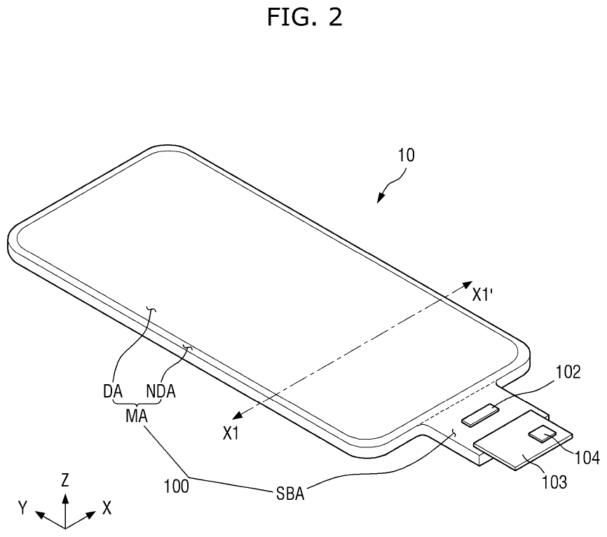

In an embodiment, the electronic device 1 may include a display device 10 in FIG. 2 providing a display screen. Examples of the display device may include an inorganic light emitting diode display device, an organic light emitting display device, a quantum dot light emitting display device, a plasma display device and a field emission display device. In the following description, a case where an organic light emitting diode display device is applied as a display device will be exemplified, but the invention is not limited thereto, and other display devices may be applied within the same scope of technical spirit.

In an embodiment, the shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes and/or a circular shape. The shape of a display area DA of the electronic device 1 may also be similar to the overall shape of the electronic device 1. FIG. 1 illustrates the electronic device 1 having a rectangular shape elongated in the second direction Y.

In an embodiment, the electronic device 1 may include the display area DA and a non-display area NDA. The display area DA is an area where a screen can be displayed, and the non-display area NDA is an area where a screen is not displayed. The display area DA may also be referred to as an active region, and the non-display area NDA may also be referred to as a non-active region. The display area DA may substantially occupy the center of the electronic device 1.

FIG. 2 is a perspective view illustrating a display device included in an electronic device, according to an embodiment.

Referring to FIG. 2, the electronic device 1 according to an embodiment may include a display device 10. The display device 10 may provide a screen displayed by the electronic device 1. The display device 10 may have a planar shape similar to the shape of the electronic device 1. For example, the display device 10 may have a shape similar to a rectangular shape having a short side in the first direction X and a long side in the second direction Y. The edge where the short side in the first direction X and the long side in the second direction Y meet may be rounded to have a curvature, but is not limited thereto and may be formed at a right angle. The planar shape of the display device 10 is not limited to a quadrilateral shape, and may be formed in a shape similar to another polygonal shape, a circular shape, and/or an elliptical shape.

In an embodiment, the display device 10 may include the display panel 100, the display driver 102, the circuit board 103, and the touch driver 104.

In an embodiment, the display panel 100 may include a main region MA and a sub-region SBA.

In an embodiment, the main region MA may include the display area DA including pixels displaying an image and the non-display area NDA disposed around the display area DA. The display area DA may emit light from a plurality of opening areas or a plurality of emission areas to be described later. For example, the display panel 100 may include a pixel circuit including switching elements, a pixel defining layer defining an emission area or an opening area, and a self-light emitting element.

For example, in an embodiment, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto. In the following drawings, an embodiment where the self-light emitting element is an organic light emitting diode is illustrated by way of example.

In an embodiment, the non-display area NDA may be an area outside the display area DA. The non-display area NDA may be defined as an edge area of the main region MA of the display panel 100. The non-display area NDA may include a gate driver (not illustrated) that supplies gate signals to the gate lines, and fan-out lines (not illustrated) that connect the display driver 102 to the display area DA.

In an embodiment, the sub-region SBA may be a region extending from one side of the main region MA. The sub-region SBA may include a flexible material which can be bent, folded and/or rolled. For example, when the sub-region SBA is bent, the sub-region SBA may overlap the main region MA in a thickness direction (e.g., the third direction Z). The sub-region SBA may include the display driver 102 and a pad portion connected to the circuit board 103. In another embodiment, the sub-region SBA may be omitted, and the display driver 102 and the pad portion may be arranged in the non-display area NDA.

In an embodiment, the display driver 102 may output signals and voltages for driving the display panel 100. The display driver 102 may supply data voltages to data lines. The display driver 102 may supply a power voltage to a power line and may supply a gate control signal to the gate driver. The display driver 102 may be formed as an integrated circuit (IC) and mounted on the display panel 100 by a chip on glass (COG) method, a chip on plastic (COP) method, or an ultrasonic bonding method. In an embodiment, the display driver 102 may be disposed in the sub-region SBA, and may overlap the main region MA in the thickness direction by bending of the sub-region SBA. In another embodiment, the display driver 102 may be mounted on the circuit board 103.

In an embodiment, the circuit board 103 may be attached to the pad portion of the display panel 100 by using an anisotropic conductive film (ACF). Lead lines of the circuit board 103 may be electrically connected to the pad portion of the display panel 100. The circuit board 103 may be a flexible printed circuit board, a printed circuit board, or a flexible film such as a chip on film.

In an embodiment, the touch driver 104 may be mounted on the circuit board 103. The touch driver 104 may be connected to a touch sensing unit of the display panel 100. The touch driver 104 may supply a touch driving signal to a plurality of touch electrodes of the touch sensing unit and may sense an amount of change in capacitance between the plurality of touch electrodes. For example, the touch driving signal may be a pulse signal having a predetermined frequency. The touch driver 104 may calculate whether an input is made and input coordinates based on an amount of change in capacitance between the plurality of touch electrodes. The touch driver 104 may be formed of an integrated circuit (IC).

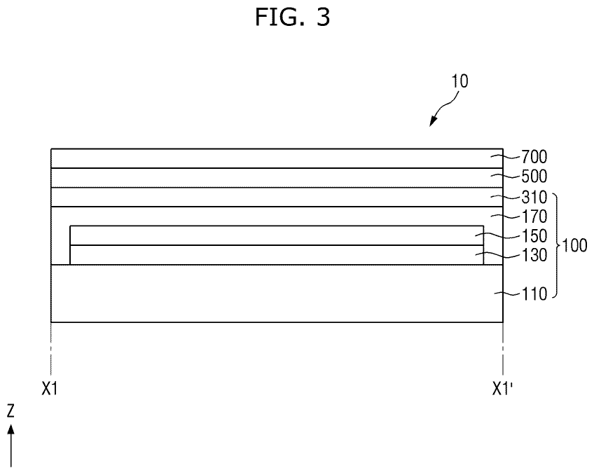

FIG. 3 is a cross-sectional view illustrating an example of a display panel taken along line X1-X1′ of FIG. 2, according to an embodiment.

In an embodiment and referring to FIG. 3, the display device 10 may include the display panel 100, a polarizing film 500, and a cover window 700, and the display panel 100 may include a substrate 110, a thin film transistor layer 130, a light emitting element layer 150, a thin film encapsulation layer 170, and a touch sensor layer 310.

In an embodiment, the substrate 110 may be formed of an insulating material such as a polymer resin. For example, the substrate 110 may be formed of polyimide. The substrate 110 may be a flexible substrate which can be bent, folded or rolled.

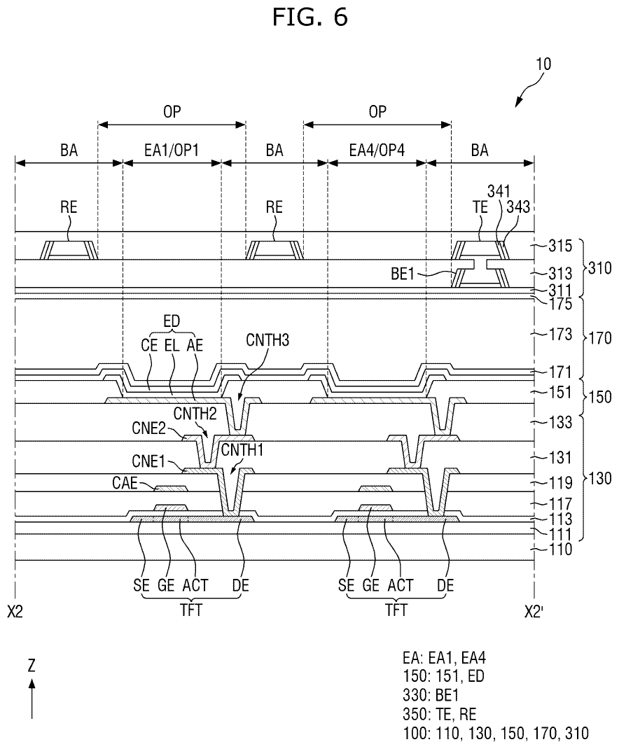

In an embodiment, the thin film transistor layer 130 may be disposed on the substrate 110. The thin film transistor layer 130 may be included in the display panel 100 and may include thin film transistors TFT which is illustrated in FIG. 6.

In an embodiment, the light emitting element layer 150 may be disposed on the thin film transistor layer 130. The light emitting layer 150 may be included in the display panel 100 and may include the light emitting element ED which is illustrated in FIG. 6.

In an embodiment, the thin film encapsulation layer 170 may be disposed on the light emitting element layer 150. The thin film encapsulation layer 170 may be disposed to cover the thin film transistor layer 130 and the light emitting element layer 150.

In an embodiment, the thin film encapsulation layer 170 may include at least one inorganic layer to prevent oxygen or moisture from permeating into the light emitting element layer 150. In addition, the thin film encapsulation layer 170 may include at least one organic layer to protect the light emitting element layer 150 from foreign substances such as dust.

In an embodiment, the touch sensor layer 310 may be disposed on the thin film encapsulation layer 170. Since the touch sensor layer 310 is directly disposed on the thin film encapsulation layer 170, it has the advantage of reducing the thickness of the display device 10 compared to a case where a separate touch panel including the touch sensor layer 310 is attached on the thin film encapsulation layer 170.

In an embodiment, the polarizing film 500 may be disposed on the touch sensor layer 310 to prevent a decrease in visibility due to reflection of external light. The polarizing film 500 may include a phase retardation film such as a linear polarizer plate and a quarter-wave (λ/4) plate.

In an embodiment, the cover window 700 may be disposed on the polarizing film 500, in which case the polarizing film 500 and the cover window 700 may be attached by an adhesive member such as an optically clear adhesive film (OCA) or an optically clear resin (OCR).

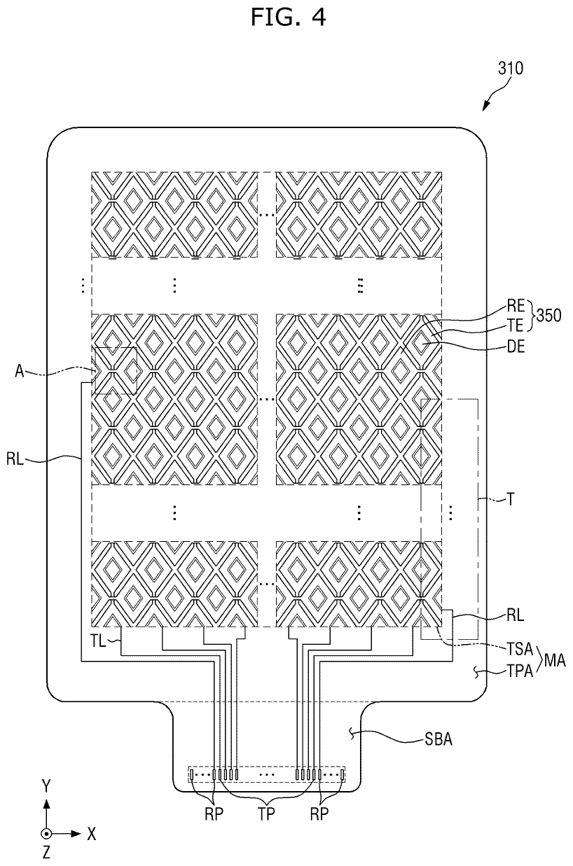

FIG. 4 is a plan view illustrating a touch sensor layer 310 of a display device, according to an embodiment.

In an embodiment and referring to FIG. 4, the touch sensor layer 310 may include a touch sensing area TSA for sensing a user's touch and a touch peripheral area TPA disposed around the touch sensing area TSA. The touch sensing area TSA may overlap the display area DA of FIGS. 1 to 3, and the touch peripheral area TPA may overlap the non-display area NDA of FIGS. 1 to 3.

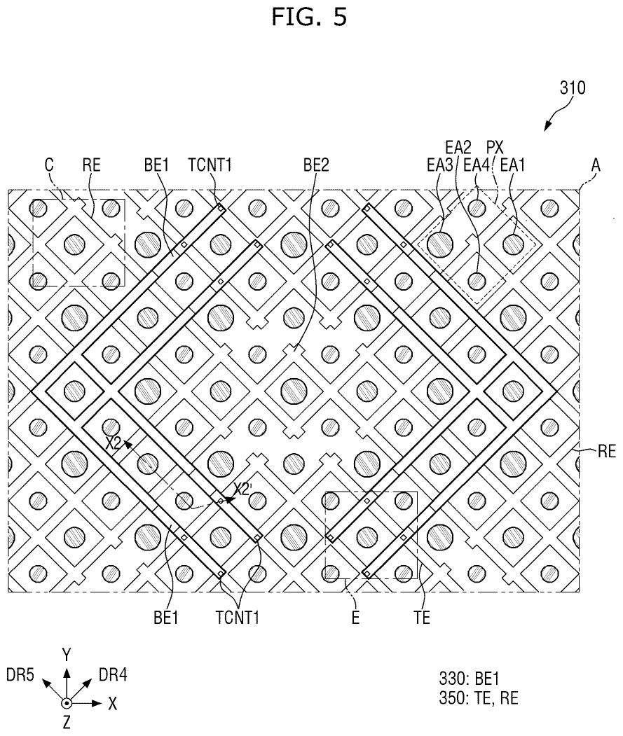

In some embodiments, the touch sensor layer 310 may include a first connection electrode BE1 (see FIG. 5) belonging to a first touch metal layer 330 (see FIG. 5), a plurality of driving electrodes TE and a plurality of sensing electrodes RE belonging to a second touch metal layer 350, a plurality of driving lines TL, a plurality of sensing lines RL, a plurality of driving pads TP, and a plurality of sensing pads RP.

In some embodiments, the plurality of driving electrodes TE and the plurality of sensing electrodes RE may be disposed in the touch sensing area TSA, whereas the plurality of driving lines TL, the plurality of sensing lines RL, the plurality of driving pads TP, and the plurality of sensing pads RP may be disposed in the touch peripheral area TPA.

In an embodiment, the plurality of driving electrodes TE may be arranged in the first direction X. For example, the plurality of driving electrodes TE may be arranged from the left side to the right side of the touch sensing area TSA. The plurality of driving electrodes TE may be electrically separated from each other, and the plurality of driving electrodes TE disposed separately may be connected to each other through the first connection electrode BE1 (see FIG. 5).

In an embodiment, each of the plurality of driving electrodes TE may be connected to the corresponding driving line TL at one side (the side where the plurality of driving pads TP and the plurality of sensing pads RP are located) of the touch sensing area TAS in the second direction Y.

In an embodiment, the plurality of sensing electrodes RE may be disposed in the second direction Y. For example, the plurality of sensing electrodes RE may be arranged from the lower side to the upper side of the touch sensing area TSA. The plurality of sensing electrodes RE may be electrically separated from each other.

In some embodiments, the sensing electrodes RE adjacent in the second direction Y may be connected to each other through a second connection electrode BE2 (see FIG. 5).

In some embodiments, the second connection electrode BE2 (see FIG. 5) may be disposed in the same layer as the sensing electrode RE belonging to the second touch metal layer 350 (see FIG. 5). Each of the plurality of sensing electrodes RE may be connected to the corresponding sensing line RL on the left side of the touch sensing area TSA. The plurality of sensing lines RL may be disposed in the touch peripheral area TPA.

In an embodiment, each of the plurality of dummy electrodes DE may be surrounded by the driving electrode TE or the sensing electrode RE. Each of the plurality of dummy electrodes DE may be electrically separated from the driving electrode TE or the sensing electrode RE. Each of the plurality of dummy electrodes DE may be disposed apart from the driving electrode TE or the sensing electrode RE. Each of the plurality of dummy electrodes DE may be electrically floating.

In an embodiment, although each of the plurality of driving electrodes TE, each of the plurality of sensing electrodes RE, and each of the plurality of dummy electrodes DE are illustrated in FIG. 4 as having a rhombic planar shape, the invention is not limited thereto. For example, each of the plurality of driving electrodes TE, each of the plurality of sensing electrodes RE, and each of the plurality of dummy electrodes DE may have a planar shape of a rectangle other than the rhombus, a polygon other than the rectangle, a circle, and/or an ellipse.

In an embodiment, the plurality of driving lines TL may be disposed at one side of the touch sensing area TSA in the second direction Y. Each of the plurality of driving pads TP may be connected to the corresponding driving line TL.

In addition, in an embodiment, some of the plurality of sensing lines RL may be disposed on the right side of the touch sensing area TSA, and the others may be disposed on the left side of the touch sensing area TSA. Each of the plurality of sensing pads RP may be connected to the corresponding sensing line RL.

In an embodiment, the plurality of driving pads TP and the plurality of sensing pads RP may be disposed in the sub-region SBA. The plurality of driving pads TP and the plurality of sensing pads RP may be electrically connected to the circuit board 103 through a conductive adhesive member such as an anisotropic conductive film.

FIG. 5 is a plan view of a touch sensor layer, presenting an enlargement of area A of FIG. 4, according to an embodiment.

In an embodiment and referring to FIG. 5, as stated above, the touch sensor layer 310 may include the plurality of driving electrodes TE and the plurality of sensing electrodes RE, which may be disposed in the same layer to be spaced apart from each other. In addition, the touch sensor layer 310 may further include the first connection electrode BE1 disposed under the plurality of sensing electrodes RE and the plurality of driving electrodes TE.

In some embodiments, the driving electrode TE, the sensing electrode RE, the first connection electrode BE1, and the second connection electrode BE2 may be formed as mesh-type electrodes. In an embodiment and as illustrated in FIG. 3, when the touch sensor layer 310 is formed directly on the thin film encapsulation layer 170, very large parasitic capacitance may be formed between the common electrode CE of the light emitting element layer 150 and the driving electrode TE or sensing electrode RE of the touch sensor layer 310 because the distance between the common electrode of the light emitting element layer 150 and the driving electrode TE or sensing electrode RE of the touch sensor layer 310 is short. Therefore, to reduce such parasitic capacitance, it may be desirable to form the driving electrodes TE and the sensing electrodes RE as the mesh-type electrodes.

In an embodiment, since the plurality of driving electrodes TE, the plurality of sensing electrodes RE, the plurality of first connection electrodes BE1, the plurality of second connection electrodes BE2, and the plurality of dummy electrodes DE are formed in the mesh structure, they may not overlap a plurality of emission areas EA1, EA2, EA3, and EA4.

Therefore, in an embodiment, the light emitted from the plurality of emission areas EA1, EA2, EA3, and EA4 may be prevented from suffering a decrease in luminance as a result of being blocked by the plurality of driving electrodes TE, the plurality of sensing electrodes RE, the plurality of first connection electrodes BE1, the plurality of second connection electrodes BE2, and the plurality of dummy electrodes DE.

In an embodiment, the driving electrode TE, the sensing electrode RE, the first connection electrode BE1, and the second connection electrode BE2 may be formed as multiple layers made of any one of molybdenum (Mo), aluminum (Al), chromium (Cr), gold (Au), titanium (Ti), nickel (Ni), neodymium (Nd) and copper (Cu) and/or an alloy thereof.

In some embodiments, the driving electrode TE may be connected to the driving electrode TE adjacent thereto in the second direction Y through touch contact holes TCNT1. In addition, the second connection electrode BE2 may be disposed in the same layer as the second touch metal layer 350 to connect the plurality of sensing electrodes RE electrically.

Meanwhile, in an embodiment as shown in FIG. 5, a fourth direction DR4 and a fifth direction DR5 may be additionally defined. The fourth direction DR4 may be a direction between one side in the first direction X and one side in the second direction Y, and the fifth direction DR5 may be a direction between the other side in the first direction X and the one side in the second direction Y.

In an embodiment, each of the plurality of pixels PX includes the first emission area EA1 emitting light of the first color, the second emission area EA2 emitting light of the second color, the third emission area EA3 emitting light of the third color, and a fourth emission area EA4 emitting light of the second color. For example, the first color may be red, the second color may be green, and the third color may be blue.

In an embodiment, in each of the plurality of pixels PX, the first emission area EA1 and the second emission area EA2 may be adjacent to each other in the fourth direction DR4, and the third emission area EA3 and the fourth emission area EA4 may be adjacent to each other in the fourth direction DR4. In each of the plurality of pixels PX, the first emission area EA1 and the fourth emission area EA4 may be adjacent to each other in the fifth direction DR5, and the second emission area EA2 and the third emission area EA3 may be adjacent to each other in the fifth direction DR5.

In an embodiment, the pixel PX including the first emission area EA1, the second emission area EA2, the third emission area EA3, and the fourth emission area EA4 may emit white light.

In an embodiment, each of the first emission area EA1, the second emission area EA2, the third emission area EA3, and the fourth emission area EA4 may have a circular planar shape, but is not limited thereto. Each of the first emission area EA1, the second emission area EA2, the third emission area EA3, and the fourth emission area EA4 may have a planar shape of a polygon such as a rectangle, or an ellipse other than the circle. Further, FIG. 5 illustrates that the third emission area EA3 has the largest area and the second emission area EA2 and the fourth emission area EA4 have the smallest area, but the invention is not limited thereto.

FIG. 6 is a cross-sectional view showing a schematic cross section taken along line X2-X2′ of FIG. 5, according to an embodiment.

A cross-sectional structure of the display device 10 will be described with reference to FIG. 6.

Since the substrate 110 has already been described above, detailed description thereof will be omitted.

In an embodiment, the thin film transistor layer 130 may include a buffer layer 111, the thin film transistor TFT, a gate insulating layer 113, a first interlayer insulating layer 117, a second interlayer insulating layer 119, a first connection electrode CNE1, a first passivation layer 131, a second connection electrode CNE2, and a second passivation layer 133.

In an embodiment, the buffer layer 111 may be disposed on the substrate 110. The buffer layer 111 may include an inorganic layer capable of preventing permeation of air or moisture. For example, the buffer layer 111 may include a plurality of inorganic layers laminated alternately.

In an embodiment, the thin film transistor TFT may be disposed on the buffer layer 111, and may constitute a pixel circuit of each of the plurality of pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

In an embodiment, the semiconductor layer ACT may overlap the gate electrode GE in the thickness direction, and may be insulated from the gate electrode GE by the gate insulating layer 113. In a part of the semiconductor layer ACT, a material of the semiconductor layer ACT may be made into a conductor to form the source electrode SE and the drain electrode DE.

In an embodiment, the gate electrode GE may be disposed on the gate insulating layer 113. The gate electrode GE may overlap the semiconductor layer ACT with the gate insulating layer 113 interposed therebetween.

In an embodiment, the gate insulating layer 113 may be disposed on the semiconductor layer ACT. For example, the gate insulating layer 113 may cover the semiconductor layer ACT and the buffer layer 111 to insulate the gate electrode GE from the semiconductor layer ACT.

In an embodiment, the first interlayer insulating layer 117 may cover the gate electrode GE and the gate insulating layer 113. The first interlayer insulating layer 117 may include a first contact hole CNTH1 through which the first connection electrode CNE1 passes.

In an embodiment, the capacitor electrode CAE may be disposed on the first interlayer insulating layer 117. The capacitor electrode CAE may overlap the gate electrode GE of the thin film transistor TFT in the third direction Z. Since the first interlayer insulating layer 117 has a predetermined dielectric constant, the capacitor electrode CAE, the gate electrode GE, and the first interlayer insulating layer 117 disposed therebetween may form a capacitor. The capacitor electrode CAE may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

In an embodiment, the second interlayer insulating layer 119 may cover the first connection electrode CNE1 and the first interlayer insulating layer 117. The second interlayer insulating layer 119 may include the first contact hole CNTH1 through which the first connection electrode CNE1 passes. The first contact hole CNTH1 may be connected to a contact hole of the gate insulating layer 113 and a contact hole of the second interlayer insulating layer 119.

In an embodiment, the first connection electrode CNE1 may be disposed on the second interlayer insulating layer 119. The first connection electrode CNE1 may electrically connect the drain electrode DE of the thin film transistor TFT to the second connection electrode CNE2. The first connection electrode CNE1 may be inserted into a contact hole provided in the second interlayer insulating layer 119, the first interlayer insulating layer 117, and the gate insulating layer 113 to be in contact with the drain electrode DE of the thin film transistor TFT.

In an embodiment, the first passivation layer 131 may cover the first connection electrode CNE1 and the second interlayer insulating layer 119. The first passivation layer 131 may protect the thin film transistor TFT. The first passivation layer 131 may include a second contact hole CNTH2 through which the second connection electrode CNE2 passes.

In an embodiment, the second connection electrode CNE2 may be disposed on the first passivation layer 131. The second connection electrode CNE2 may electrically connect the first connection electrode CNE1 to a pixel electrode AE of the light emitting element ED. The second connection electrode CNE2 may be in contact with the first connection electrode CNE1 through the second contact hole CNTH2 formed in the first passivation layer 131.

In an embodiment, the second passivation layer 133 may cover the second connection electrode CNE2 and the first passivation layer 131. The second passivation layer 133 may include a third contact hole CNTH3 through which the pixel electrode AE of the light emitting element ED passes.

In an embodiment, the light emitting element layer 150 may be disposed on the thin film transistor layer 130. The light emitting element layer 150 may include the light emitting element ED and a pixel defining layer 151. The light emitting element ED may include the pixel electrode AE, a light emitting layer EL, and a common electrode CE.

In an embodiment, the pixel electrode AE may be disposed on the second passivation layer 133. The pixel electrode AE may be disposed to overlap any one of a plurality of openings defined by the pixel defining layer 151. The pixel electrode AE may be electrically connected to the drain electrode DE of the thin film transistor TFT through the first connection electrode CNE1 and the second connection electrode CNE2.

In some embodiments, the plurality of pixel defining layers 151 positioned in the first direction may define a first opening OP1. The pixel defining layer 151 may be disposed on portions of the second passivation layer 133 and the pixel electrode AE, and the first opening OP1 may expose a portion of the pixel electrode AE. As described above, the respective first openings OP1 of the pixel defining layer 151 may define the first to fourth emission areas EA1, EA2, EA3, and EA4, respectively, and their areas or sizes may be different from each other.

In other words, in an embodiment, the area defined by the first opening OP1 may be defined as the emission area EA, and each of the plurality of pixels PX may include the first to fourth emission areas EA1, EA2, EA3, and EA4, respectively. FIG. 6 is a cross-sectional view taken along line X2-X2′ of FIG. 5, illustrating the first emission area EA1 and the fourth emission area EA4.

In an embodiment, the pixel defining layer 151 may separate and insulate the pixel electrode AE of each of the plurality of light emitting elements ED. The pixel defining layer 151 may include a light absorbing material to prevent light reflection. The area, other than the emission area EA, overlapping the plurality of pixel defining layers 151 may be defined as a non-emission area BA.

In some embodiments, the pixel defining layer 151 may contain a polyimide (PI)-based binder and a pigment in which red, green and blue are mixed, and/or may contain a cardo-based binder resin, a mixture of a lactam-based black pigment and a blue pigment, and carbon black.

In an embodiment, the light emitting layer EL may be an organic light emitting layer made of an organic material. In the case of employing the organic light emitting layer as the light emitting layer EL, the thin film transistor TFT applies a predetermined voltage to the pixel electrode AE of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

In an embodiment, the common electrode CE may be disposed on the light emitting layer EL and the pixel defining layer 151. In addition, the common electrode CE may be formed over the entire display area DA (see FIG. 2) in the form of an electrode common to all of the pixels rather than specific to each of the pixels.

In an embodiment, the common electrode CE may receive the common voltage or a low potential voltage. When the pixel electrode AE receives a voltage corresponding to a data voltage and the common electrode CE receives the low potential voltage, a potential difference is formed between the pixel electrode AE and the common electrode CE, so that the light emitting layer EL may emit light.

In an embodiment, the thin film encapsulation layer 170 may be disposed on the common electrode CE to cover the plurality of light emitting elements ED. In some embodiments, the thin film encapsulation layer 170 may include at least one inorganic layer and at least one organic layer, thereby preventing foreign substances such as oxygen, moisture, or dust from penetrating into the light emitting element layer 150.

In an embodiment, the thin film encapsulation layer 170 may include a first thin film encapsulation layer 171, a second thin film encapsulation layer 173, and a third thin film encapsulation layer 175 sequentially stacked in the third direction Z. The first thin film encapsulation layer 171 and the third thin film encapsulation layer 175 may be inorganic layers, and the second thin film encapsulation layer 173 disposed between them may be an organic layer.

In an embodiment, each of the first thin film encapsulation layer 171 and the third thin film encapsulation layer 175 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

In an embodiment, the second thin film encapsulation layer 173 may include a polymer-based material. Examples of the polymer-based material may include acrylic resin, epoxy resin, polyimide, polyethylene and the like. For example, the organic encapsulation layer 173 may include an acrylic resin, for example, polymethyl methacrylate, polyacrylic acid, or the like. The second thin film encapsulation layer 173 may be formed by curing a monomer or applying a polymer.

In an embodiment, the touch sensor layer 310 may be positioned on the third thin film encapsulation layer 175. The touch sensor layer 310 may include a touch buffer layer 311, the first touch metal layer 330, the touch insulating layer 313, the second touch metal layer 350, a touch protection layer 315, a low reflection layer 341, and a passivation layer 343.

In some embodiments, the touch buffer layer 311, the touch insulating layer 313, and the touch protection layer 315 may be positioned to overlap the emission area EA and the non-emission area BA, and the first touch metal layer 330, the second touch metal layer 350, the low reflection layer 341, and the passivation layer 343 may be positioned to overlap the non-emission area BA.

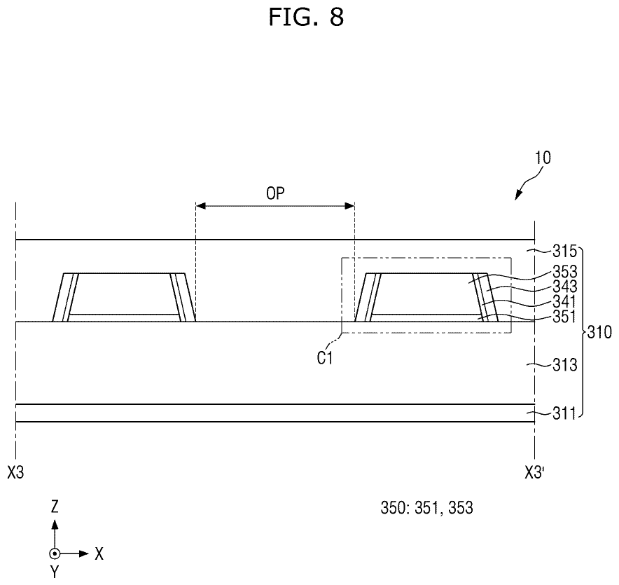

Details of the touch sensor layer 310 will be described later in FIG. 8.

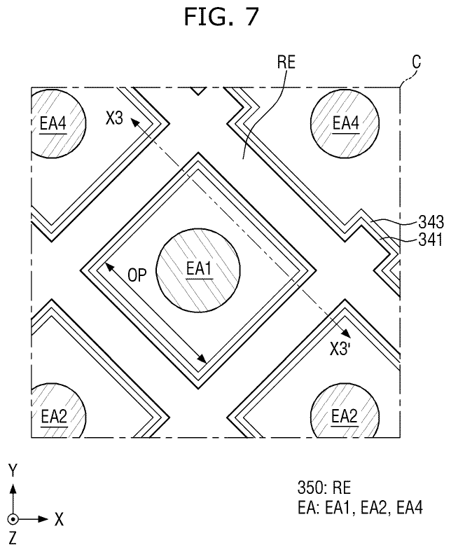

FIG. 7 is an enlarged plan view of area C of FIG. 5, according to an embodiment.

In an embodiment and referring to FIG. 7, the display device 10 may include the low reflection layer 341 and the passivation layer 343 disposed to surround the side surfaces of the second touch metal layer 350. The low reflection layer 341 may be disposed to surround the side surfaces of the second touch metal layer 350 in the direction toward the emission area EA. In addition, the passivation layer 343 may be disposed on the low reflection layer 341 to surround the side surfaces of the second touch metal layer 350, and the low reflection layer 341 in the direction toward the emission area EA.

As mentioned above, in an embodiment the second touch metal layer 350 may be formed in a mesh shape or a net shape, and, besides, the low reflection layer 341 and the passivation layer 343 disposed to surround the side surfaces of the second touch metal layer 350 may also be formed in a mesh shape or a net shape.

In some embodiments, as the low reflection layer 341 and the passivation layer 343 are formed in the mesh structure, an opening OP overlapping the emission area EA may be defined. In other words, the low reflection layer 341 and the passivation layer 343 including the opening OP and formed on the side surfaces of the second touch metal layer 350 may not overlap the plurality of emission areas EA1, EA2, EA3, and EA4 of each of the pixels PX shown in FIG. 5.

In an embodiment, although FIG. 7 illustrates only the second touch metal layer 350 for simplicity of description, the first touch metal layer 330 may have the same planar structure as the second touch metal layer 350.

FIG. 8 is a cross-sectional view showing a schematic cross section taken along line X3-X3′ of FIG. 7, according to an embodiment.

To elaborate, in an embodiment and referring to FIG. 8, the touch sensor layer 310 may include the touch buffer layer 311, the touch insulating layer 313, the second touch metal layer 350, the touch protection layer 315, the low reflection layer 341, and the passivation layer 343.

In an embodiment, the touch buffer layer 311 may be formed of an inorganic layer, for example, a silicon nitride layer, a silicon oxynitride layer, a silicon oxide layer, a titanium oxide layer, and/or an aluminum oxide layer.

In an embodiment, the touch insulating layer 313 may be disposed on the touch buffer layer 311. The touch insulating layer 313 may be formed of an inorganic layer, for example, a silicon nitride layer, a silicon oxynitride layer, a silicon oxide layer, a titanium oxide layer, and/or an aluminum oxide layer. Alternatively, the touch insulating layer 313 may be formed of an organic layer such as acryl resin, epoxy resin, phenolic resin, polyamide resin, polyimide resin and the like.

In an embodiment, the second touch metal layer 350 may be disposed on the touch insulating layer 313. The second touch metal layer 350 may include the driving electrodes TE and the sensing electrodes RE, and, besides, the dummy electrodes DE, the driving lines TL, and the sensing lines RL illustrated in FIG. 4 and may be disposed in the same layer as the second touch metal layer 350. In other words, the dummy electrodes DE, the driving lines TL, and the sensing lines RL may be disposed on the touch insulating layer 313.

In some embodiments, the second touch metal layer 350 may be formed as multiple layers made of any one of metals such as molybdenum (Mo), aluminum (Al), chromium (Cr), gold (Au), titanium (Ti), nickel (Ni), neodymium (Nd) and copper (Cu) or an alloy thereof. In other words, the second touch metal layer 350 may be formed as a double layer or a triple layer.

In some embodiments, the second touch metal layer 350 of the display device 10 may have a double-layer structure including Ti/Cu.

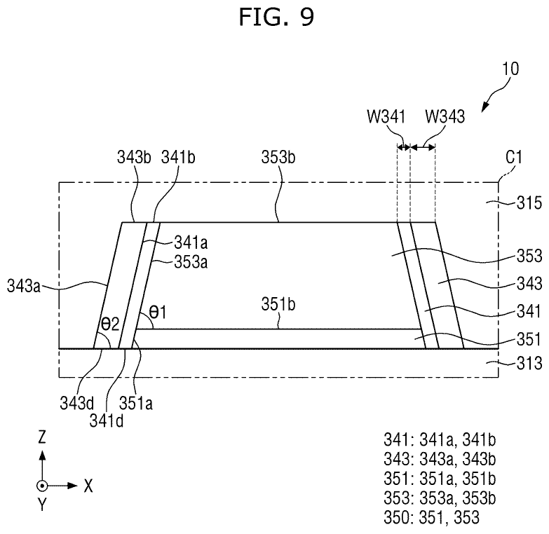

In some embodiments, the low reflection layer 341 and the passivation layer 343 may be disposed on both side surfaces of the second touch metal layer 350 in the first direction X. Detailed structures and characteristics of the second touch metal layer 350, the low reflection layer 341, and the passivation layer 343 will be described later in FIG. 9.

In an embodiment, the touch protection layer 315 may be disposed on the second touch metal layer 350 and the touch insulating layer 313.

In an embodiment, the touch protection layer 315 may serve to planarize a step formed by the second touch metal layer 350 and the touch insulating layer 313. The touch protection layer 315 may be formed of an organic layer such as acryl resin, epoxy resin, phenolic resin, polyamide resin, polyimide resin and the like.

FIG. 9 is an enlarged cross-sectional view of area C1 of FIG. 8, according to an embodiment.

In an embodiment and as illustrated in FIG. 9, the second touch metal layer 350 may include a first conductive layer 351 and a second conductive layer 353, and the low reflection layer 341 and the passivation layer 343 may be disposed on the side surfaces of the first conductive layer 351 and the second conductive layer 353.

In some embodiments, the first conductive layer 351 may be disposed on the touch insulating layer 313. The first conductive layer 351 may be formed of, for example, titanium (Ti) through deposition. Without being limited to titanium (Ti), however, the first conductive layer 351 may be any one of molybdenum (Mo), chromium (Cr), tungsten (W), nickel chromium (NiCr), titanium tungsten alloy (TiW), and copper (Cu), or an alloy of at least two of them.

In some embodiments, the first conductive layer 351 may include one surface in contact with the touch insulating layer 313, a flat surface 351b located on the opposite side of the one surface in contact with the touch insulating layer 313, and an inclined surface 351a connecting the one surface in contact with the touch insulating layer 313 to the flat surface 351b.

In an embodiment, the second conductive layer 353 may be disposed on the first conductive layer 351. The second conductive layer 353 may be, for example, copper (Cu). Without being limited thereto, however, the second conductive layer 353 may be any one of gold (Au), silver (Ag), and copper (Cu), and/or an alloy including at least one of them.

In some embodiments, the second conductive layer 353 may include one surface in contact with the first conductive layer 351, a flat surface 353b located on the opposite side of the one surface in contact with the first conductive layer 351, and an inclined surface 353a connecting the one surface in contact with the first conductive layer 351 to the flat surface 353b.

In some embodiments, when the angle formed by the flat surface 351b of the first conductive layer 351 and the inclined surface 353a of the second conductive layer 353 is defined as a first inclination angle θ1, the first inclination angle θ1 may be an acute angle. Further, the first inclination angle θ1 may be in the range of about 60° to about 90°.

In some embodiments, the low reflection layer 341 may be disposed on the inclined surface 351a of the first conductive layer 351 and the inclined surface 353a of the second conductive layer 353.

In other words, in an embodiment, the low reflection layers 341 may be disposed on both side surfaces of the second touch metal layer 350 of the display device 10 in the first direction X. For example, the low reflection layer 341 may be disposed along and in contact with the inclined surface 351a of the first conductive layer 351 and the inclined surface 353a of the second conductive layer 353.

In some embodiments, the low reflection layer 341 may be formed of an inorganic layer such as, but not limited to, amorphous silicon (a-Si), silicon carbonite (SiC), and/or a mixture of them.

In some embodiments, the low reflection layer 341 may include an inclined surface 341a disposed to face the inclined surface 351a of the first conductive layer 351 and the inclined surface 353a of the second conductive layer 353, and a flat surface 341b disposed to extend in parallel to the flat surface 353b of the second conductive layer 353.

In an embodiment, the passivation layer 343 may be disposed on the inclined surface 341a of the low reflection layer 341.

In some embodiments, the passivation layer 343 may include an inclined surface 343a disposed to face the inclined surface 341a of the low reflection layer 341, and a flat surface 343b disposed to extend in parallel to the flat surface 353b of the second conductive layer 353 and the flat surface 341b of the low refection layer 341.

In some embodiments, the passivation layer 343 may be an inorganic layer, for example, a silicon nitride layer and/or a silicon oxynitride layer. The inorganic layer included in the low reflection layer 341 may have lower reflectivity than the inorganic layer included in the passivation layer 343.

In some embodiments, the manufacturing process for the second touch metal layer 350 may include a dry etching process, and the passivation layer 343 may serve to protect the low reflection layer 341 from being etched during the dry etching process.

In some embodiments, the flat surface 353b of the second conductive layer 353, the flat surface 341b of the low reflection layer 341, and the flat surface 343b of the passivation layer 343 may be arranged flat in the direction parallel to the first direction X while being in contact with the touch protection layer 315.

In other words, in an embodiment, the flat surface 353b of the second conductive layer 353, the flat surface 341b of the low reflection layer 341, and the flat surface 343b of the passivation layer 343 that are in contact with the touch protection layer 315 may be arranged at the same height in the first direction X to be aligned on the same plane.

In some embodiments, the low reflection layer 341 may further include one surface 341d positioned opposite to the flat surface 341b thereof, and the passivation layer 343 may further include one surface 343d positioned opposite to the flat surface 343b thereof. The one surface 341d of the low reflection layer 341 and the one surface 343d of the passivation layer 343 may be in contact with the touch insulating layer 313.

In other words, in an embodiment and as shown in FIG. 9, the one surface 341d of the low reflection layer 341 and the one surface 343d of the passivation layer 343 disposed toward the substrate 110 are in contact with the touch insulating layer 313, and the other surface 341b of the low reflection layer 341 and the other surface 343b of the passivation layer 343 positioned opposite to the one surface 341d of the low reflection layer 341 and the one surface 343d of the passivation layer 343, respectively, may be disposed to be in contact with the touch protection layer 315.

In an embodiment, when the angle formed by the touch insulating layer 313 and the inclined surface 343a of the passivation layer 343 is defined as a second inclination angle θ2, the second inclination angle θ2 may be an acute angle. In some embodiments, the second inclination angle θ2 may be in the range of about 600 to about 90°.

In some embodiments, a thickness W341 of the low reflection layer 341 in the first direction X may be smaller than a thickness W343 of the passivation layer 343.

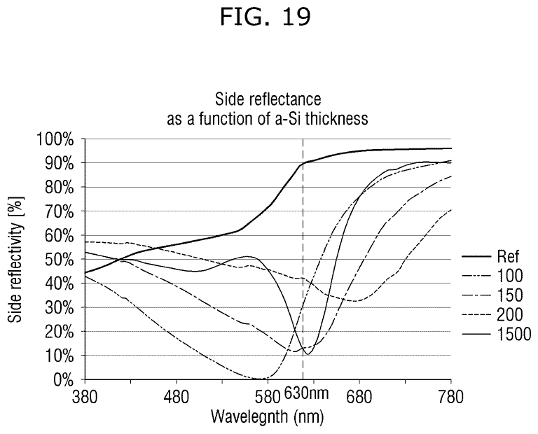

In some embodiments, the thickness W341 of the low reflection layer 341 may affect the side reflectivity of the display device 10, which will be described in detail in FIG. 19.

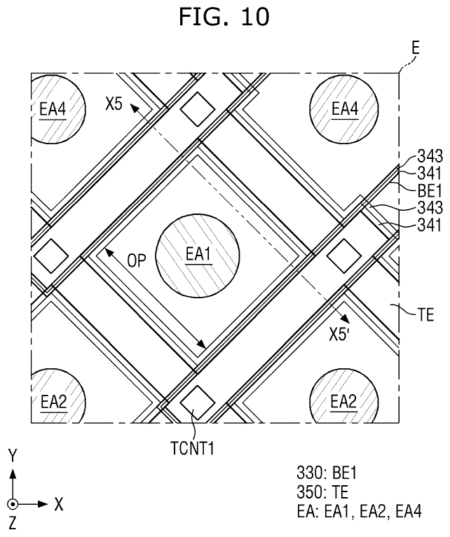

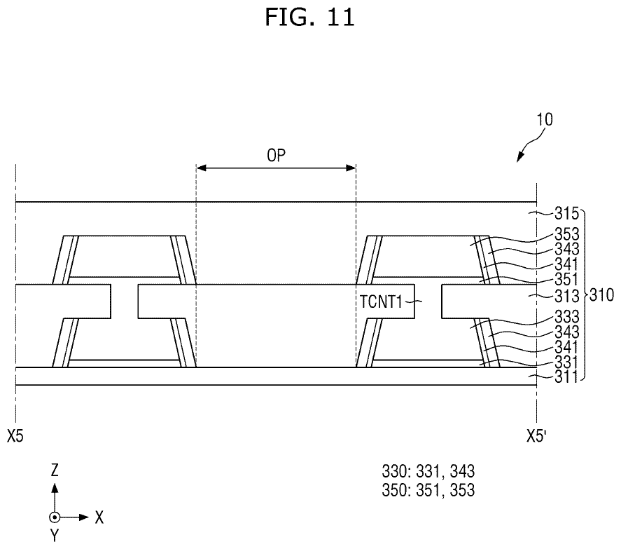

FIG. 10 is an enlarged plan view of area E of FIG. 5, according to an embodiment, and FIG. 11 is a cross-sectional view showing a schematic cross section taken along line X5-X5′ of FIG. 10, according to an embodiment.

Referring to FIGS. 10 and 11, the first touch metal layer 330 including the first connection electrode BE1 may be formed in a layer different from the layer where the second touch metal layer 350. The driving electrode TE belonging to the second touch metal layer 350 may be electrically connected to the first connection electrode BE1 belonging to the first touch metal layer 330 through the touch contact hole TCNT1.

In some embodiments, the first touch metal layer 330 and the second touch metal layer 350 may be formed in a mesh shape or a net shape, and, besides, the low reflection layer 341 and the passivation layer 343, which are disposed to surround the side surfaces of the first touch metal layer 330 and the second touch metal layer 350, may also be formed in a mesh shape or a net shape.

In an embodiment, the first touch metal layer 330 may be formed as multiple layers made of any one of metals such as molybdenum (Mo), aluminum (Al), chromium (Cr), gold (Au), titanium (Ti), nickel (Ni), neodymium (Nd) and copper (Cu) and/or an alloy thereof. In other words, the first touch metal layer 330 may be formed as a double layer or a triple layer. For example, the first touch metal layer 330 of the display device 10 may include a Ti/Cu structure.

Referring to FIG. 11, in an embodiment, the touch sensor layer 310 may include the touch buffer layer 311, the first touch metal layer 330, the touch insulating layer 313, the second touch metal layer 350, the low reflection layer 341, the passivation layer 343, and the touch protection layer 315.

In some embodiments, the first touch metal layer 330 may include a first conductive layer 331 and a second conductive layer 333. The first conductive layer 331 may be disposed on the touch buffer layer 311. The first conductive layer 331 may be the same material as the first conductive layer 351 of the second touch metal layer 350. For example, the first conductive layer 331 may be formed of, for example, titanium (Ti) through deposition. Without being limited to titanium (Ti), however, the first conductive layer 331 may be any one of molybdenum (Mo), chromium (Cr), tungsten (W), nickel chromium (NiCr), titanium tungsten alloy (TiW), and copper (Cu).

In an embodiment, the second conductive layer 333 of the first touch metal layer 330 may be disposed on the first conductive layer 331 of the first touch metal layer 330. The second conductive layer 333 of the first touch metal layer 330 may be the same material as the second conductive layer 353 of the second touch metal layer 350. For example, the second conductive layer 333 of the first touch metal layer 330 may include at least one of gold (Au), silver (Ag), or copper (Cu).

In an embodiment, the low reflection layer 341 and the passivation layer 343 may be disposed on the side surface of the first touch metal layer 330. In other words, the low reflection layer 341 may be disposed on the side surfaces of the first conductive layer 331 of the first touch metal layer 330 and the second conductive layer 333 of the first touch metal layer 330. In addition, the passivation layer 343 may be disposed on the low reflection layer 341.

In an embodiment, the layout and characteristics of the low reflection layer 341 and the passivation layer 343 belonging to the first touch metal layer 330 may be the same as the layout and characteristics of the low reflection layer 341 and the passivation layer 343 belonging to the second touch metal layer 350.

In some embodiments, the top surface of the second conductive layer 333 of the first touch metal layer 330, the top surface of the low reflection layer 341, and the top surface of the passivation layer 343 may be in contact with the touch insulating layer 313, and the top surface of the second conductive layer 333, the top surface of the low reflection layer 341, and the top surface of the passivation layer 343 may be disposed to extend side by side in the first direction X. In other words, the top surface of the second conductive layer 333, the top surface of the low reflection layer 341, and the top surface of the passivation layer 343 that are in contact with the touch insulating layer 313 may be arranged at the same height in the first direction X to be aligned on the same plane.

In addition, in an embodiment, the top surface of the low reflection layer 341 and the top surface of the passivation layer 343 may be in contact with the touch insulating layer 313, and the bottom surface of the low reflection layer 341 and the bottom surface of the passivation layer 343 located on the opposite side from the top surfaces in the third direction Z may be disposed to be in contact with the touch buffer layer 311.

Since the second touch metal layer 350 has already been described, redundant description thereof will be omitted here.

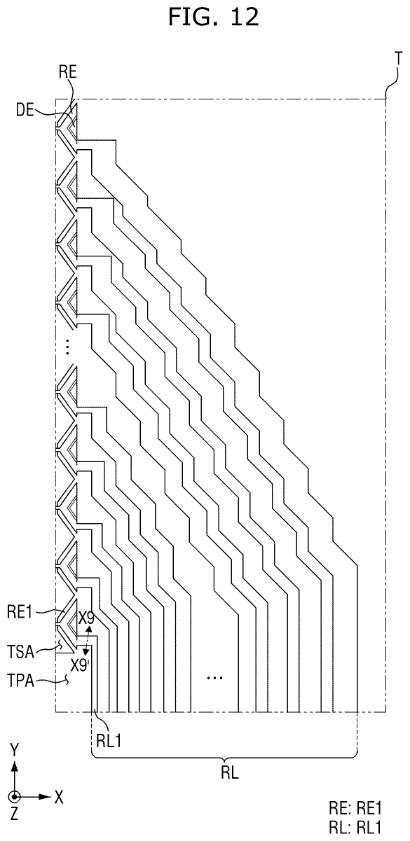

FIG. 12 is an enlarged plan view of area T of FIG. 4, according to an embodiment.

In an embodiment and as shown in FIG. 12, each of the sensing electrodes RE may be connected to a corresponding sensing line RL on the right side of the touch sensing area TSA. For example, when the sensing electrode RE, which is located at the bottom right (direction toward the touch pad) in the first direction X, as a first sensing electrode RE1, the first sensing electrode RE1 may be connected to a first sensing line RL1 in the touch peripheral area TPA.

In some embodiments, the plurality of sensing lines RL may be disposed in the touch peripheral area TPA that is disposed in the periphery of the touch sensing area TSA. The plurality of sensing lines RL may be disposed in the same layer as the second touch metal layer 350 that includes the sensing electrodes RE and the driving electrodes TE.

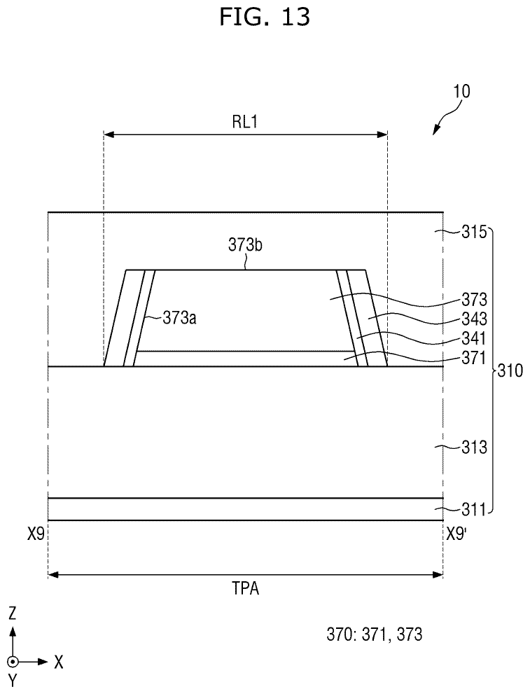

FIG. 13 is a cross-sectional view illustrating a schematic cross section taken along line X9-X9′ of FIG. 12, according to an embodiment.

In an embodiment and referring to FIG. 13, the touch sensor layer 310 of the touch peripheral area TPA may include the touch buffer layer 311, the touch insulating layer 313, a first touch metal layer 370, the low reflection layer 341, the passivation layer 343, and the touch protection layer 315.

In some embodiments, the first touch metal layer 370 may include a first conductive layer 371 disposed on the touch insulating layer 313, and a second conductive layer 373 disposed on the first conductive layer 371. In addition, the low reflection layer 341 and the passivation layer 343 covering the low reflection layer 341 may be disposed on the side surfaces of the first conductive layer 371 of the first touch metal layer 370 and the second conductive layer 373 of the first touch metal layer 370.

In an embodiment, the structure of the first touch metal layer 370 of the display device 10 may be the same as the first touch metal layer 330 and the second touch metal layer 350 included in the display device 10.

For example, in an embodiment, the structure and characteristics of the first conductive layer 371 of the first touch metal layer 370 may be the same as those of the first conductive layer 351 of the second touch metal layer 350 of the display device 10. Further, the structure and characteristics of the second conductive layer 373 of the first touch metal layer 370 may be the same as those of the second conductive layer 353 of the second touch metal layer 350 of the display device 10.

Since the second touch metal layer 350 has been described, it will be omitted in the following descriptions.

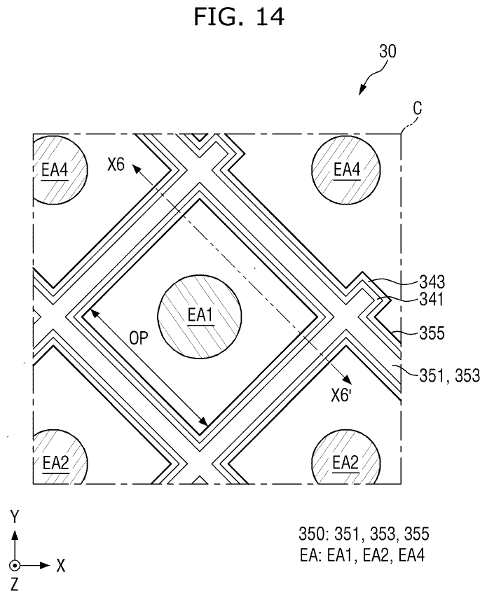

FIG. 14 is an enlarged plan view of area C of FIG. 5 according to another embodiment.

In an embodiment, the touch sensor layer 310 of a display device 30 may be different from that of the display device 10 in that the second touch metal layer 350 includes a third conductive layer 355 on the second conductive layer 353.

In an embodiment and as shown in FIG. 14, in the case of the display device 30, the low reflection layer 341 may be disposed to surround the side surfaces of the first conductive layer 351 and the second conductive layer 353 and face the emission area EA, and the passivation layer 343 may be disposed to surround the side surface of the low reflection layer 341 and face the emission area EA. Further, in the display device 30, the third conductive layer 355 may be disposed to cover the first conductive layer 351, the second conductive layer 353, the low reflection layer 341, and the passivation layer 343.

In an embodiment and for simplicity of illustration, FIG. 14 shows the first conductive layer 351, the second conductive layer 353, the low reflection layer 341, and the passivation layer 343 as being visibly recognized. However, in reality, the first conductive layer 351, the second conductive layer 353, the low reflection layer 341, and the passivation layer 343 of the display device 30 may not be visible because the third conductive layer 355 is disposed to cover all of the first conductive layer 351, the second conductive layer 353, the low reflection layer 341, and the passivation layer 343 in a plan view.

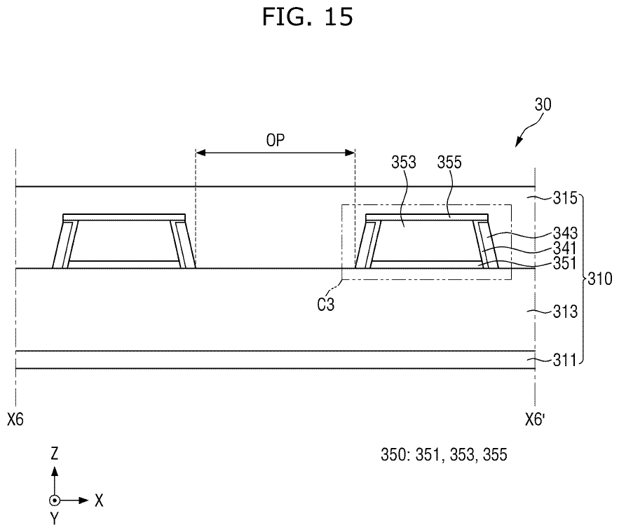

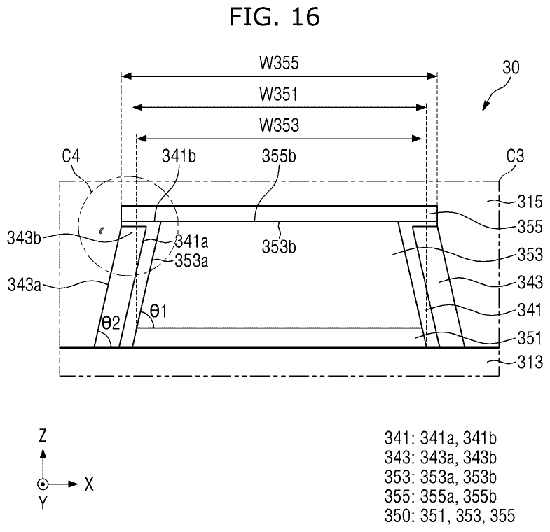

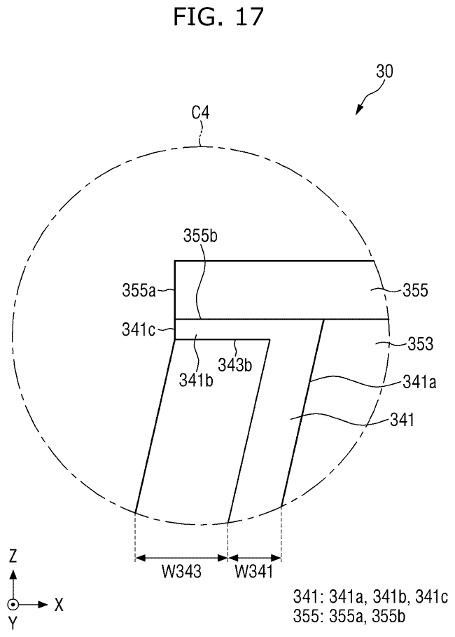

FIG. 15 is a cross-sectional view showing a schematic cross section taken along line X6-X6′ of FIG. 14 according to another embodiment. FIG. 16 is an enlarged cross-sectional view of area C3 of FIG. 13 according to another embodiment. FIG. 17 is an enlarged cross-sectional view of area C4 of FIG. 16, according to an embodiment.

Referring to FIGS. 15 to 17, the third conductive layer 355 included in the second touch metal layer 350 of the display device 30 may be disposed to be in partial contact with the flat surface 353b of the second conductive layer 353.

In some embodiments, the third conductive layer 355 may be formed of, for example, titanium (Ti) through deposition. Without being limited to the titanium (Ti), however, the third conductive layer 355 may be any one of molybdenum (Mo), chromium (Cr), tungsten (W), nickel chromium (NiCr), titanium tungsten alloy (TiW), and copper (Cu), and/or an alloy of at least two of them.

In an embodiment and referring to FIG. 16, a width W351 of the first conductive layer 351 may be smaller than a width W355 of the third conductive layer 355 in the first direction X. Further, a width W353 of the second conductive layer 353 may be smaller than the width W351 of the first conductive layer 351 and the width W355 of the third conductive layer 355. Thus, in the second touch metal layer 350 of the display device 30, the third conductive layer 355 may be disposed to cover the first conductive layer 351 and the second conductive layer 353.

In some embodiments, the low reflection layer 341 may be disposed on both side surfaces of the first conductive layer 351 and the second conductive layer 353 of the display device 30. The low reflection layer 341 may be disposed to be in contact with the inclined surface 353a of the second conductive layer 353. The low reflection layer 341 may include the inclined surface 341a disposed to face the inclined surface 353a of the second conductive layer 353.

In some embodiments, the passivation layer 343 may be disposed on the inclined surface 341a of the low reflection layer 341. The passivation layer 343 may include the inclined surface 343a disposed to face the inclined surface 341a of the low reflection layer 341.

In an embodiment, the low reflection layer 341 of the display device 30 may be disposed such that the flat surface 341b of the low reflection layer 341 covers the flat surface 343b of the passivation layer 343. Further, it is different from the display device 10 in that the flat surface 341b of the low reflection layer 341 may be disposed to be in contact with one surface 355b of the third conductive layer 355 facing the second conductive layer 353, but the flat surface 343b of the passivation layer 343 is not disposed to be in contact with the one surface 355b of the third conductive layer 355. That is, the flat surface 343b of the passivation layer 343 may not be disposed to extend to the same height as the flat surface 341b of the low reflection layer 341, but may be covered by the flat surface 341b of the low reflection layer 341. In other words, the flat surface 343b of the passivation layer 343 may not be in contact with the one surface 355b of the third conductive layer 355.

In some embodiments, the flat surface 341b of the low reflection layer 341 and the flat surface 353b of the second conductive layer 353 of the display device 30 may be disposed to be flat in a direction parallel to the first direction X. That is, the flat surface 341b of the low reflection layer 341 and the flat surface 353b of the second conductive layer 353 may be arranged at the same height in the first direction X to be aligned on the same plane.

However, in an embodiment, the flat surface 343b of the passivation layer 343 of the display device 30 may not be disposed to extend to the same height as the flat surface 353b of the second conductive layer 353. Further, the flat surface 341b of the low reflection layer 341 and the flat surface 343b of the passivation layer 343 of the display device 30 may be disposed in parallel while being spaced apart from each other in the third direction Z.

In an embodiment and referring to FIG. 17, a side surface 355a of the third conductive layer 355 of the display device 30 and a side surface 341c of the low reflection layer 341 of the display device 30 may be disposed to extend side by side in the third direction Z with their ends aligned.

In some embodiments, the thickness W341 of the low reflection layer 341 in the first direction X may be smaller than the thickness W343 of the passivation layer 343. The thickness W341 of the low reflection layer 341 may affect the side reflectivity of the display device 30 according to its size, which will be described in detail with reference to FIG. 19.

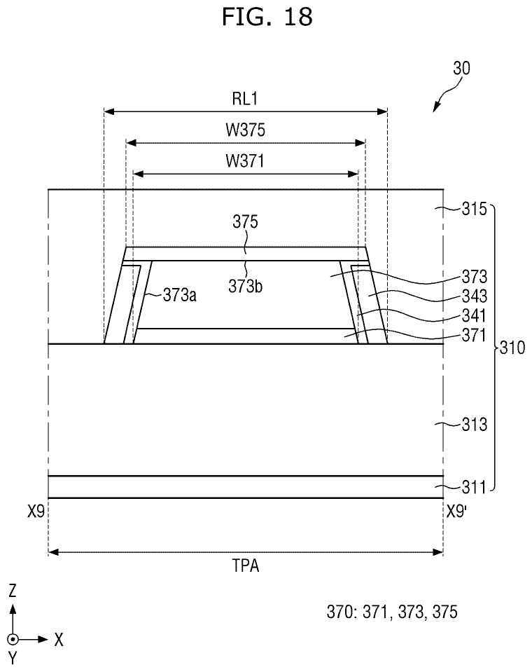

FIG. 18 is a cross-sectional view showing a schematic cross section taken along line X9-X9′ of FIG. 12, according to another embodiment.

Referring to FIG. 18, the first touch metal layer 370 of the display device 30 may include the first conductive layer 371, the second conductive layer 373, and a third conductive layer 375.

In an embodiment, the first conductive layer 371 may be disposed on the touch insulating layer 313, the second conductive layer 373 may be disposed on the first conductive layer 371, and the third conductive layer 375 may be disposed on the second conductive layer 373 while covering the first conductive layer 371 and the second conductive layer 373. In addition, the low reflection layer 341 and the passivation layer 343 covering the low reflection layer 341 may be disposed on the side surfaces of the first conductive layer 371 and the second conductive layer 373. One surface of the third conductive layer 375 may be disposed to be in contact with the second conductive layer 373 and the low reflection layer 341.

In some embodiments, a width W371 of the first conductive layer 371 may be smaller than a width W375 of the third conductive layer 375 in the first direction X. The third conductive layer 375 may be positioned to cover the first conductive layer 371 and the second conductive layer 373.

In some embodiments, the structure of the first touch metal layer 370 of the display device 30 may be the same as the second touch metal layer 350 included in the display device 30. For example, the characteristics and structure of the first conductive layer 371 of the display device 30 may be the same as those of the first conductive layer 351 of the display device 30, the characteristics and structure of the second conductive layer 373 of the display device 30 may be the same as those of the second conductive layer 353 of the display device 30, and the characteristics and structure of the third conductive layer 375 of the display device 30 may be the same as those of the third conductive layer 355 of the display device 30.

In an embodiment and for simplicity of description, the second touch metal layer 350 has been mainly described in the case of the display device 30. However, the display device 30 may include the first touch metal layer 330 similarly to the display device 10, and the first touch metal layer 330 of the display device 30 may include the same structure as the second touch metal layer 350 of the display device 30. Further, the first touch metal layer 330 and the second touch metal layer 350 of the display device 30 may be electrically connected to each other through the touch contact hole TCNT1 penetrating the touch insulating layer 313.

FIG. 19 is a graph showing side reflectivity for each wavelength according to the thickness W341 of the low reflection layer 341, according to an embodiment.

As described above, in an embodiment, in the display device 10 and the display device 30, the side reflectivities of the display device 10 and the display device 30 may depend on the thickness W341 of the low reflection layer 341, which is disposed on the inclined surface 353a of the second conductive layer 353, in the first direction X. In the display device 10 and the display device 30, the first touch metal layer 330 and the second touch metal layer 350 may include copper (Cu) which may be seen as being reddish according to a viewing angle due to reflection light scattered from a side portion of each of the display device 10 and the display device 30. Therefore, the display device 10 and the display device 30 need to have less side reflections at wavelengths near about 630 nm.

In the graph of FIG. 19, an X-axis may represent wavelength (nm), and a Y-axis may represent side reflectivity (%), according to an embodiment.

In some embodiments, line Ref shown in FIG. 19 may be the side reflectivity of a display device that does not include the low reflection layer 341, as a comparative example. Further, lines shown in addition to line Ref may represent the side reflectivity of the display device measured while varying the thickness W341 of the low reflection layer 341 to about 100 Å, about 150 Å, about 200 Å, and about 1500 Å.

In an embodiment and referring to FIG. 19, in the case of the display device that does not include the low reflection layer 341, the side reflectivity may be about 90% at a wavelength, at which it may be seen reddish from the outside due to side reflection, for example, at a wavelength near about 630 nm. However, in the cases of display devices 10 and 30 including the low reflection layer 341, the side reflectivity may be lower than about 90% at a wavelength near about 630 nm. For example, when the thickness W341 of the low reflection layer 341 is about 150 Å, the side reflectivities of the display device 10 and the display device 30 may be reduced to about 10%. Thus, it is possible to reduce deterioration in quality of the display device 10 and the display device 30, which may be recognized by a user.

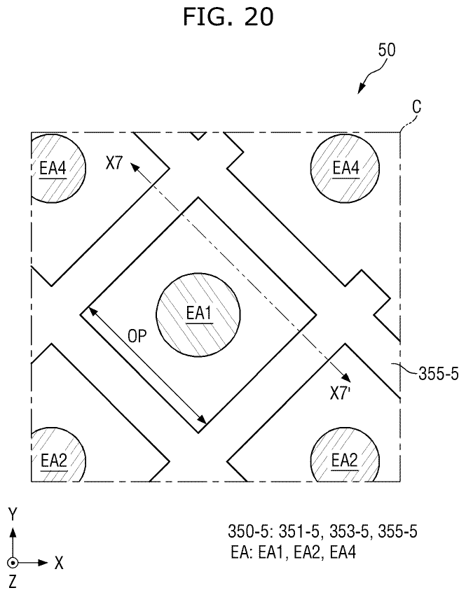

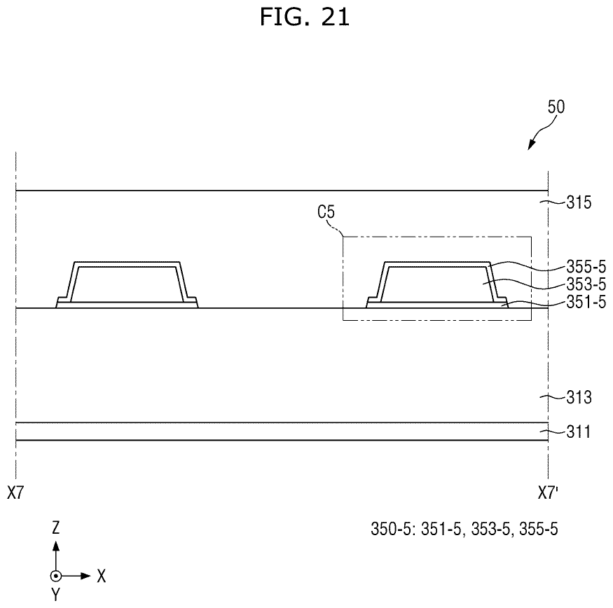

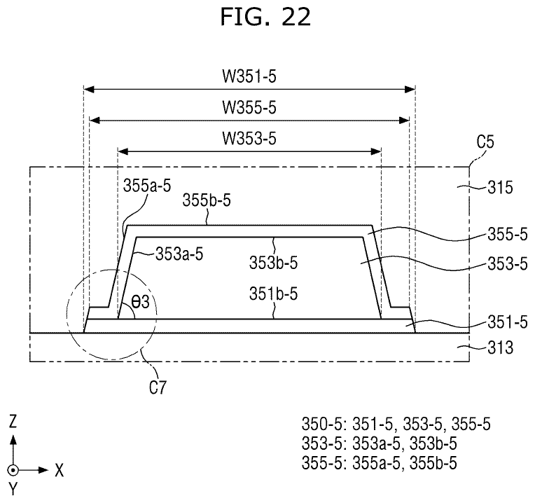

FIG. 20 is an enlarged plan view of area C of FIG. 5, according to another embodiment. FIG. 21 is a cross-sectional view illustrating a schematic cross-section taken along line X7-X7′ of FIG. 20, according to another embodiment. FIG. 22 is an enlarged cross-sectional view of area C5 of FIG. 21, according to an embodiment.

In an embodiment, the touch sensor layer 310 of the display device 50 may be different from those of the display device 10 and the display device 30 in that it does not include the low reflection layer 341 and the passivation layer 343, but instead includes a first-fifth conductive layer 351-5, a second-fifth conductive layer 353-5, and a third-fifth conductive layer 355-5 that have different structures and properties.

In an embodiment and referring to FIG. 20, a second-fifth touch metal layer 350-5 may be formed in a mesh shape. As the second-fifth touch metal layer 350-5 are formed in a mesh shape, an opening OP may be formed to overlap the emission area EA.

In an embodiment and referring to FIG. 21, the touch sensor layer 310 of the display device 50 may include the touch buffer layer 311, the touch insulating layer 313, the second-fifth touch metal layer 350-5, and the touch protection layer 315.

In some embodiments, the touch insulator layer 313 may be disposed on the touch buffer layer 311. In addition, the second-fifth touch metal layer 350-5 may be disposed on the touch insulating layer 313, and the touch protection layer 315 may be disposed on the touch insulating layer 313 and the second-fifth touch metal layer 350-5.

In an embodiment and referring to FIG. 22, the second-fifth touch metal layer 350-5 of the display device 50 may include the first-fifth conductive layer 351-5, the second-fifth conductive layer 353-5, and the third-fifth conductive layer 355-5.

In some embodiments, the first-fifth conductive layer 351-5 of the display device 50 may be disposed on the touch insulating layer 313. For example, the first-fifth conductive layer 351-5 may be titanium nitride (TiN). Without being limited to titanium nitride (TiN), the first-fifth conductive layer 351-5 may be any one of titanium oxide (TiO₂), chromium oxide (CrO₂), copper oxide (CuO), nickel oxide (NiO), aluminum oxide (Al₂O₃), silver oxide (AgO), and copper nitride (CuN).

In some embodiments, the second-fifth conductive layer 353-5 may be disposed on the first-fifth conductive layer 351-5. The second-fifth conductive layer 353-5 may be, for example, copper (Cu). Without being limited thereto, however, the second conductive layer 353 may be any one of gold (Au), silver (Ag), and copper (Cu), or an alloy including at least one of them.

In some embodiments, the second-fifth conductive layer 353-5 may include a flat surface 353b-5 that is in contact with the third-fifth conductive layer 355-5 and an inclined surface 353a-5 that is a side surface of the second-fifth conductive layer 353-5. A width W353-5 of the second-fifth conductive layer 353-5 may be smaller than a width W351-5 of the first-fifth conductive layer 351-5 in the first direction X.

In some embodiments, when defining an angle formed by one surface 351b-5 of the first-fifth conductive layer 351-5 facing the second-fifth conductive layer 353-5 and the inclined surface 353a-5 of the second-fifth conductive layer 353-5 as a third inclination angle θ3, the third inclination angle θ3 may be an acute angle. For example, the third inclination angle θ3 may range from about 60° to about 90°.

In an embodiment, the third-fifth conductive layer 355-5 may be disposed on the second-fifth conductive layer 353-5 while covering a part of the first-fifth conductive layer 351-5 and the second-fifth conductive layer 353-5.

In an embodiment, the third-fifth conductive layer 355-5 may include a flat surface 355b-5 positioned to face the flat surface 353b-5 of the second-fifth conductive layer 353-5 and an inclined surface 355a-5 positioned to face the inclined surface 353a-5 of the second-fifth conductive layer 353-5.

In some embodiments, similarly to the first-fifth conductive layer 351-5, the third-fifth conductive layer 355-5 of the display device 50 may be titanium nitride (TiN). Without being limited to titanium nitride (TiN), the third-fifth conductive layer 355-5 may be any one of titanium oxide (TiO₂), chromium oxide (CrO₂), copper oxide (CuO), nickel oxide (NiO), aluminum oxide (Al₂O₃), silver oxide (AgO), and copper nitride (CuN). For example, titanium nitride (TiN) may include the characteristics of a low reflective inorganic layer.

In an embodiment, the manufacturing process of the second-fifth touch metal layer 350-5 of the display device 50 may include a dry etching process. During the dry etching process of the first-fifth conductive layer 351-5 and the third-fifth conductive layer 355-5 including titanium nitride (TiN), it is possible to prevent a dry etching phenomenon that may be caused by titanium oxide (TiOx) formation.

In some embodiments, a width W355-5 of the third-fifth conductive layer 355-5 may be greater than a width W353-5 of the second-fifth conductive layer 353-5 and may be smaller than or equal to a width W351-5 of the first-fifth conductive layer 351-5 in the first direction. In other words, the second-fifth conductive layer 353-5 may be completely covered by the first-fifth conductive layer 351-5 and the third-fifth conductive layer 355-5 so as not to be in contact with the touch insulating layer 313 and the touch protection layer 315.

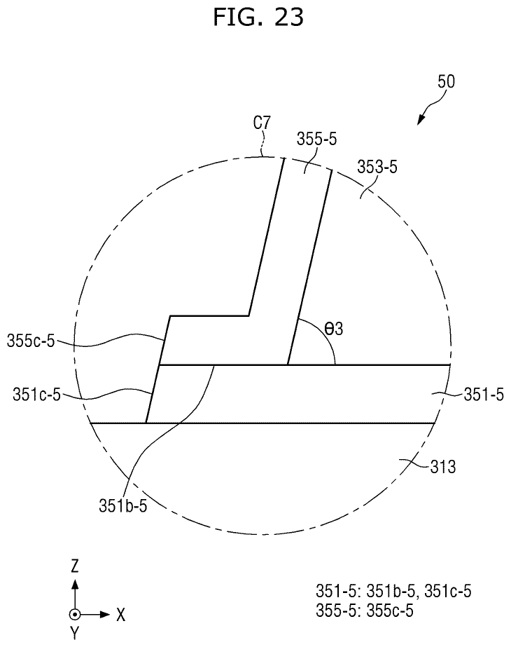

FIG. 23 is an enlarged cross-sectional view of area C7 of FIG. 22, according to an embodiment.

In an embodiment and referring to FIG. 23, in the display device 50, a side surface 351c-5 of the first-fifth conductive layer 351-5 and a side surface 355c-5 of the third-fifth conductive layer 355-5 may be in contact with the touch protection layer 315. The side surface 351c-5 of the first-fifth conductive layer 351-5 and the side surface 355c-5 of the third-fifth conductive layer 355-5 may be aligned on the same plane. In other words, the side surface 351c-5 of the first-fifth conductive layer 351-5 and the side surface 355c-5 of the third-fifth conductive layer 355-5 may be aligned and extend on the same line. Further, the flat surface 351b-5 of the first-fifth conductive layer 351-5 of the display device 50 may be in contact with the third-fifth conductive layer 355-5 at both end portions thereof in the first direction X.

In some embodiments, the second-fifth conductive layer 353-5 may not be located in a portion where the flat surface 351b-5 of the first-fifth conductive layer 351-5 is in contact with the third-fifth conductive layer 355-5.

In an embodiment and for simplicity of description, the second-fifth touch metal layer 350-5 of the display device 50 has been mainly described, but the display device 50 may include the first-fifth touch metal layer 330-5 in the same manner as the display device 10 and the display device 30. In addition, the first-fifth touch metal layer 330-5 of the display device 50 may include the same structure as the second-fifth touch metal layer 350-5 of the display device 50. The first-fifth touch metal layer 330-5 may be electrically connected to the second-fifth touch metal layer 350-5 through the touch contact hole TCNT1 penetrating the touch insulating layer 313.

Since a detailed description has been made, it will be omitted in the following descriptions.

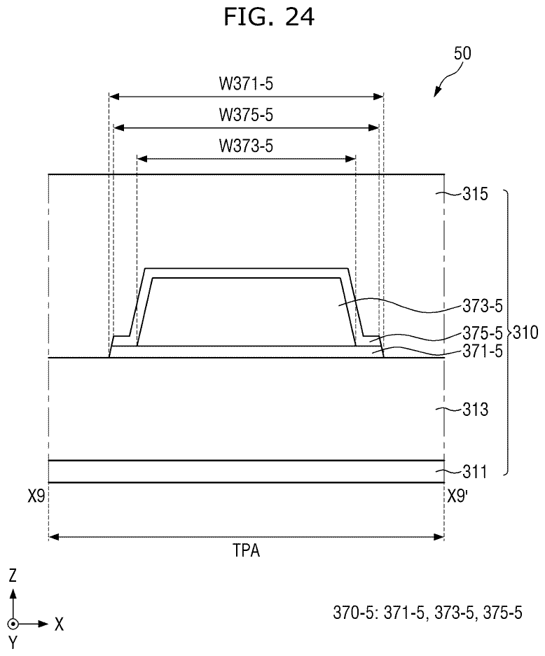

FIG. 24 is a cross-sectional view showing a schematic cross section taken along line X9-X9′ of FIG. 13, according to still another embodiment.

In an embodiment and referring to FIG. 24, a second touch metal layer 370-5 of the display device 50 may be different from the display device 10 in that it does not include the low reflection layer 341 and the passivation layer 343, but instead includes a first-fifth conductive layer 371-5, a second-fifth conductive layer 373-5, and a third-fifth conductive layer 375-5 that have different structures and properties.

In an embodiment, the first-fifth conductive layer 371-5 of the display device 50 may be disposed on the touch insulating layer 313, the second-fifth conductive layer 373-5 may be disposed on the first-fifth conductive layer 371-5, and the third-fifth conductive layer 375-5 may be disposed on the second-fifth conductive layer 373-5.

In some embodiments, in the second touch metal layer 370-5, a width W373-5 of the second-fifth conductive layer 373-5 may be smaller than a width W371-5 of the first-fifth conductive layer 371-5 and a width W375-5 of the third-fifth conductive layer 375-5 in the first direction X. Further, the width W371-5 of the first-fifth conductive layer 371-5 may be greater than or equal to the width W375-5 of the third-fifth conductive layer 375-5. Thus, the third-fifth conductive layer 375-5 of the second touch metal layer 370-5 may completely cover the second-fifth conductive layer 373-5.

In an embodiment, the structure of the second touch metal layer 370-5 of the display device 50 may be the same as the structure of the second-fifth touch metal layer 350-5 included in the display device 50. For example, the structure and characteristics of the first-fifth conductive layer 371-5 of the second touch metal layer 370-5 may be the same as those of the first-fifth conductive layer 351-5 of the second-fifth touch metal layer 350-5, the structure and characteristics of the second-fifth conductive layer 373-5 of the second touch metal layer 370-5 may be the same as those of the second-fifth conductive layer 353-5 of the second-fifth touch metal layer 350-5, and the structure and characteristics of the third-fifth conductive layer 375-5 of the second touch metal layer 370-5 may be the same as those of the third-fifth conductive layer 355-5 of the second-fifth touch metal layer 350-5.

Since a detailed description has been made, it will be omitted in the following descriptions.

In some embodiments, in the display device 50, the second-fifth conductive layer 353-5 of the second-fifth touch metal layer 350-5 and the second-fifth conductive layer 373-5 of the second touch metal layer 370-5 may be, for example, copper (Cu). They may be one of gold (Au), silver (Ag), and copper (Cu), or an alloy containing at least one thereof.

In an embodiment and as described with reference to FIG. 19, copper (Cu), which is contained in the second-fifth conductive layer 353-5 of the second touch metal layer 350-5 and the second-fifth conductive layer 373-5 of the second touch metal layer 370-5, may be seen as being reddish from the outside of the display device 50 according to a viewing angle due to reflection light from the side.

In some embodiments, in the display device 50, the first-fifth conductive layer 351-5 and the third-fifth conductive layer 355-5 of the second-fifth touch metal layer 350-5, and the first-fifth conductive layer 371-5 and the third-fifth conductive layer 375-5 of the second touch metal layer 370-5 may have the characteristics of a low reflective inorganic layer. Accordingly, the display device 50 is capable of minimizing scattering of light and thus improving the side reflectivity recognized from the outside of the display device 50. In other words, the display device 50 including the characteristics of a low reflective inorganic layer is capable of reducing a phenomenon of being seen as reddish from the outside of the display device. Thus, it is possible to reduce deterioration in quality of the display device, which may be recognized by a user.

The invention should not be construed as being limited to the embodiments set forth herein. Rather, these embodiments are provided so that this disclosure will be thorough and complete and will fully convey the invention to those skilled in the art. While the invention has been particularly shown and described with reference to embodiments thereof, it will be understood by those of ordinary skill in the art that various changes in form and details may be made therein without departing from the spirit or scope of the invention as defined by the following claims. Moreover, the embodiments or parts of the embodiments may be combined in whole or in part without departing from the scope of the invention.

What is claimed is:

1. A touch sensing unit comprising:
a substrate comprising an emission area and a non-emission area;
a light emitting element positioned on the substrate and overlapping the emission area;
a thin film encapsulation layer on the light emitting element and overlapping the emission area and the non-emission area; and
a touch sensor layer on the thin film encapsulation layer,
wherein the touch sensor layer comprises:
a touch insulating layer on the thin film encapsulation layer and overlapping the emission area and the non-emission area;
a touch metal layer on the touch insulating layer and overlapping the non-emission area;
a low reflection layer on the touch metal layer;
a passivation layer on the low reflection layer; and
a touch protection layer on the touch insulating layer and the passivation layer and overlapping the emission area and the non-emission area,
wherein the touch metal layer comprises:
a first conductive layer on the touch insulating layer; and
a second conductive layer on the first conductive layer,
wherein the second conductive layer comprises a first surface in contact with the first conductive layer, a second surface opposite to the first surface, and a first inclined surface connecting the first surface to the second surface,
wherein the passivation layer is positioned on the first inclined surface of the second conductive layer,
wherein the low reflection layer is positioned between the first inclined surface of the second conductive layer and the passivation layer, and comprising a third surface positioned to face the touch protection layer, and
wherein the second surface of the second conductive layer and the third surface of the low reflection layer are aligned in a first direction and are positioned on the same plane.

2. The touch sensing unit of claim 1, wherein the passivation layer further comprises a fourth surface positioned to face the touch protection layer, and
wherein the second surface of the second conductive layer, the third surface of the low reflection layer, and the fourth surface of the passivation layer are aligned in the first direction and positioned on the same plane.

3. The touch sensing unit of claim 2, wherein the low reflection layer and the passivation layer are disposed on the touch insulating layer in partial contact therewith, wherein the second conductive layer is not in contact with the touch insulating layer.

4. The touch sensing unit of claim 3, wherein the first conductive layer further comprises a second inclined surface extending from the first inclined surface of the second conductive layer, and
wherein the second inclined surface is in contact with the low reflection layer.

5. The touch sensing unit of claim 3, wherein a first inclination angle formed by one surface of the first conductive layer in contact with the second conductive layer and the first inclined surface of the second conductive layer ranges from about 60° to about 90°.

6. The touch sensing unit of claim 4, wherein a thickness of the low reflection layer in the first direction is smaller than a thickness of the passivation layer,
a thickness of the low reflection layer in the first direction ranges from about 100 Å to about 200 Å,
the low reflection layer contains amorphous silicon (a-Si) and silicon carbonite (SiC), and
the passivation layer comprises an inorganic layer.

7. The touch sensing unit of claim 1, wherein the first conductive layer and the second conductive layer are formed in a mesh shape, and
the passivation layer and the low reflection layer are formed in a mesh shape to surround side surfaces of the first conductive layer and the second conductive layer.

8. The touch sensing unit of claim 7, further comprising an opening formed by the passivation layer and the low reflection layer,
wherein the opening overlaps the emission area.

9. The touch sensing unit of claim 1, wherein the touch metal layer further comprises a third conductive layer disposed on the second conductive layer,
one surface of the third conductive layer facing the second conductive layer is in partial contact with the third surface, and
a first side surface of the third conductive layer and a second side surface of the low reflection layer are aligned on the same plane in a direction perpendicular to the first direction.

10. The touch sensing unit of claim 9, wherein the passivation layer further comprises a fourth surface positioned to face the touch protection layer, wherein one surface of the third conductive layer facing the second conductive layer is not in contact with the fourth surface.

11. The touch sensing unit of claim 10, wherein a width of the third conductive layer in the first direction is greater than a width of the first conductive layer in the first direction.

12. The touch sensing unit of claim 11, wherein the first conductive layer and the third conductive layer contain titanium (Ti), and wherein the second conductive layer contains copper (Cu).

13. The touch sensing unit of claim 1, further comprising:
a connection electrode overlapping the non-emission area and positioned between the thin film encapsulation layer and the touch insulating layer; and
a touch contact hole passing through a center of the touch insulating layer,
wherein the connection electrode and the touch metal layer are electrically connected by the touch contact hole.

14. The touch sensing unit of claim 13, wherein the touch metal layer comprises a driving electrode and a sensing electrode.

15. A touch sensing unit comprising:
a substrate comprising an emission area and a non-emission area;
a light emitting element positioned on the substrate and overlapping the emission area;
a thin film encapsulation layer on the light emitting element and overlapping the emission area and the non-emission area; and
a touch sensor layer positioned on the thin film encapsulation layer,
wherein the touch sensor layer comprises:
a touch insulating layer on the thin film encapsulation layer and overlapping the emission area and the non-emission area;
a touch metal layer on the touch insulating layer and overlapping the non-emission area; and
a touch protection layer on the touch metal layer,
wherein the touch metal layer comprises:
a first conductive layer on the touch insulating layer;
a second conductive layer on the first conductive layer, the second conductive layer comprising a first surface in contact with the first conductive layer, a second surface disposed opposite to the first surface, and a first inclined surface connecting the first surface to the second surface; and
a third conductive layer covering the first inclined surface and the second surface
wherein the first side surface located at both ends of the first conductive layer in the first direction and the second side surface located at both ends of the third conductive layer in the first direction are aligned on the same plane.

16. The touch sensing unit of claim 15, wherein a width of the first conductive layer in the first direction is greater than a width of the second conductive layer, and greater than or equal to a width of the third conductive layer.

17. The touch sensing unit of claim 16, wherein an angle formed by one surface of the first conductive layer in contact with the second conductive layer and the first inclined surface of the second conductive layer ranges from about 60° to about 90°.

18. The touch sensing unit of claim 17, wherein the first conductive layer and the third conductive layer contain titanium nitride (TiN), and wherein the second conductive layer contains copper (Cu).

19. A touch sensing unit comprising:
a substrate comprising a display area having an emission area and a non-emission area and a non-display area;
a thin film encapsulation layer on the substrate and overlapping the display area and the non-display area;
a touch insulating layer on the thin film encapsulation layer and overlapping the display area and the non-display area;
a touch electrode on the touch insulating layer and overlapping the non-emission area;
a touch signal line on the touch insulating layer and overlapping the non-display area;
a low reflection layer overlapping the non-display area and positioned on the touch signal line;
a passivation layer overlapping the non-display area and positioned on the low reflection layer; and
a touch protection layer overlapping the display area and the non-display area and positioned on the passivation layer,
wherein the touch signal line comprises:
a first conductive layer on the touch insulating layer; and
a second conductive layer on the first conductive layer,
wherein the second conductive layer comprises a first surface in contact with the first conductive layer, a second surface disposed opposite to the first surface, and a first inclined surface connecting the first surface to the second surface,
wherein the passivation layer is positioned on the first inclined surface,
wherein the low reflection layer is positioned between the first inclined surface and the passivation layer,
wherein the low reflection layer further comprises a third surface disposed to face the touch protection layer, and
wherein the second surface and the third surface are aligned on the same plane.

20. The touch sensing unit of claim 19, wherein the touch signal line further comprises a third conductive layer disposed on the second conductive layer,
wherein one surface of the third conductive layer is disposed in partial contact with the third surface, and
wherein a side surface of the third conductive layer and a side surface of the low reflection layer are aligned in a direction perpendicular to the first direction.
